(19) United States
(12) Patent Application Publication
(10) Pub. No.: US 2025/0070739 A1
(43) Pub. Date: Feb. 27, 2025

(54) PIEZOELECTRIC RESONATOR DEVICE AND METHOD FOR ADJUSTING FREQUENCY OF PIEZOELECTRIC RESONATOR DEVICE

(71) Applicant: DAISHINKU CORPORATION, Kakogawa-shi, Hyogo (JP)

(72) Inventor: Manabu MARUMOTO, Kakogawa-shi (JP)

(73) Assignee: DAISHINKU CORPORATION, Kakogawa-shi, Hyogo (JP)

(21) Appl. No.: 18/721,119

(22) PCT Filed: Dec. 27, 2022
(86) PCT No.: PCT/JP2022/048143

§ 371 Date: Jun. 17, 2024

(30) Foreign Application Priority Data
Jan. 21, 2022 (JP) 2022-008170
Jan. 25, 2022 (JP) 2022-009290
Jan. 31, 2022 (JP) 2022-013237

(51) Int. Cl. H03H 3/04; H03H 9/02; H03H 9/10

(52) U.S. Cl. CPC H03H 3/04; H03H 9/02125; H03H 9/1035; H03H 2003/0478

(57) ABSTRACT

In a frequency adjustment method of a crystal resonator according to an embodiment, a frequency adjustment metal film made of a base metal layer and a metal layer laminated thereon is formed on a first main surface, facing a second excitation electrode, of a second sealing member made of crystal. The frequency adjustment is performed by: irradiating the frequency adjustment metal film with a laser from an outside of the second sealing member so that the laser penetrates an interior thereof and heats the base metal layer; and melting and evaporating at least part of the metal layer so that the evaporated metal layer is adhered to the second excitation electrode. The melting temperature of the base metal layer is higher than the melting temperature of the metal layer, and the difference therebetween is not less than 1500 K.

### TECHNICAL FIELD

The present invention relates to a piezoelectric resonator device and a method for adjusting a frequency of the piezoelectric resonator device.

### BACKGROUND ART

Conventionally, the manufacturing process of a piezoelectric resonator device such as a crystal resonator includes a frequency adjustment step. In this frequency adjustment step, the frequency of the crystal resonator is adjusted in a target frequency range (see, for example, Patent Document 1).

When the frequency adjustment step is performed after a vibrating part of a crystal resonator plate is sealed by a sealing member, a beam such as a laser is emitted from the outside of the crystal resonator. In this case, if the beam power is extremely large, an excitation electrode of the vibrating part may be damaged. Also, scattering matters and/or gas may be generated in the internal space of the crystal resonator.

### PRIOR ART DOCUMENT

### Patent Document

[Patent Document 1] JP 5762811

### SUMMARY OF THE INVENTION

### Problem to be Solved by the Invention

The present invention was made in consideration of the above circumstances, an object of which is to provide a piezoelectric resonator device and a method for adjusting a frequency of a piezoelectric resonator device, in which the frequency adjustment is easily performed without degrading the characteristics of the piezoelectric resonator device even after a vibrating part of a piezoelectric resonator plate is sealed by a sealing member.

### Means for Solving the Problem

In order to solve the above problem, in a piezoelectric resonator device according to a first aspect of the present invention, a vibrating part having an excitation electrode is hermetically sealed by a sealing member. A frequency adjustment metal film made of a base metal layer and a metal layer laminated thereon is formed on a main surface of the sealing member on a side facing the excitation electrode. The base metal layer has a melting temperature higher than a melting temperature of the metal layer. The difference between the melting temperature of the base metal layer and the melting temperature of the metal layer is not less than 1500 K.

Also, in order to solve the above problem, in a piezoelectric resonator device according to a second aspect of the present invention, a vibrating part having an excitation electrode is hermetically sealed by a sealing member. A frequency adjustment metal film made of a base metal layer and a metal layer laminated thereon is formed on a main surface of the sealing member on a side facing the excitation electrode. A material of the metal layer is selected from the group consisting of Au (gold), Ag (silver), and Al (aluminum). A material of the base metal layer is selected from the group consisting of W (tungsten), Mo (molybdenum), Ta (tantalum), and Re (rhenium).

Also, in order to solve the above problem, in a method for adjusting a frequency of a piezoelectric resonator device according to a third aspect of the present invention, a vibrating part having an excitation electrode is hermetically sealed by a sealing member. The piezoelectric resonator device is the above-described piezoelectric resonator device. The method includes the steps of: irradiating the frequency adjustment metal film with a beam from an outside of the sealing member so that the beam penetrates an interior of the sealing member and heats the base metal layer; and melting and evaporating at least part of the metal layer so that an evaporated part of the metal layer is adhered to the excitation electrode.

With the above-described configuration, the metal layer disposed on the base metal layer is melted and evaporated, and the evaporated metal is adhered to the excitation electrode to increase the mass of the excitation electrode. Thus, the frequency can be shifted to the lower side. At this time, since the melting temperature of the base metal layer is sufficiently higher than the melting temperature of the metal layer, it is possible to reliably melt and evaporate only the metal layer. Therefore, it is possible to perform the frequency adjustment without considerably degrading the characteristics of the piezoelectric resonator device even after sealing the vibrating part by the sealing member.

### Effects of the Invention

In the piezoelectric resonator device of the present invention as well as the method for adjusting a frequency of a piezoelectric resonator device of the present invention, the metal layer disposed on the base metal layer is melted and evaporated, and the evaporated metal is adhered to the excitation electrode. Thus, it is possible to perform the frequency adjustment of the piezoelectric resonator device even after sealing the vibrating part. At this time, by setting the melting temperature of the base metal layer to be sufficiently higher than the melting temperature of the metal layer, it is possible to reliably melt and evaporate only the metal layer.

### BRIEF DESCRIPTION OF THE DRAWINGS

FIG. 1 is a schematic configuration diagram schematically illustrating a configuration of a crystal resonator.

FIG. 2 is a schematic plan view illustrating a first main surface of a first sealing member of the crystal resonator.

FIG. 3 is a schematic plan view illustrating a second main surface of the first sealing member of the crystal resonator.

FIG. 4 is a schematic plan view illustrating a first main surface of a crystal resonator plate.

FIG. 5 is a schematic plan view illustrating a second main surface of the crystal resonator plate.

FIG. 6 is a schematic plan view illustrating a first main surface of a second sealing member of the crystal resonator.

FIG. 7 is a schematic plan view illustrating a second main surface of the second sealing member of the crystal resonator.

FIG. 8 is a schematic cross-sectional view schematically illustrating a method for adjusting the frequency of the crystal resonator according to a first embodiment.

FIG. 9 is a schematic cross-sectional view schematically illustrating a frequency adjustment metal film of the crystal resonator according to the first embodiment.

FIG. 10 is a schematic cross-sectional view corresponding to FIG. 8, which illustrates the frequency adjustment metal film of the crystal resonator according to a variation of the first embodiment.

FIG. 11 is a schematic plan view schematically illustrating a method for irradiating the frequency adjustment metal film with a laser according to the first embodiment.

FIG. 12 is a schematic plan view corresponding to FIG. 6, which illustrates the first main surface of the second sealing member of the crystal resonator according to a variation of the first embodiment.

FIG. 13 is a schematic cross-sectional view corresponding to FIG. 8, which illustrates the method for adjusting the frequency of the crystal resonator according to a variation of the first embodiment.

FIG. 14 is a schematic plan view illustrating the first main surface of the second sealing member of the crystal resonator according to a second embodiment.

FIG. 15 is a schematic cross-sectional view schematically illustrating the method for adjusting the frequency of the crystal resonator according to the second embodiment.

FIG. 16 is a schematic cross-sectional view corresponding to FIG. 15, which illustrates the frequency adjustment metal film of the crystal resonator according to a variation of the second embodiment.

FIG. 17 is a schematic plan view schematically illustrating the method for irradiating the frequency adjustment metal film with a laser according to the second embodiment.

FIG. 18 is a schematic plan view schematically illustrating the method for irradiating the frequency adjustment metal film with a laser according to a comparative example of the second embodiment.

FIG. 19 is a schematic plan view schematically illustrating a laser irradiation range to the frequency adjustment metal film according to the second embodiment.

FIG. 20 are schematic cross-sectional views each schematically illustrating a production step of the frequency adjustment metal film of the crystal resonator according to the second embodiment.

FIG. 21 are enlarged cross-sectional views of the frequency adjustment metal film according to the second embodiment. FIG. 21(a) shows a state before the frequency adjustment, and FIG. 21(b) shows a state after the frequency adjustment.

FIG. 22 is a schematic plan view corresponding to FIG. 14, which illustrates the first main surface of the second sealing member of the crystal resonator according to a variation of the second embodiment.

FIG. 23 is a schematic cross-sectional view corresponding to FIG. 15, which illustrates the method for adjusting the frequency of the crystal resonator according to a variation of the second embodiment.

FIG. 24 is a schematic plan view illustrating the second main surface of the second sealing member of the crystal resonator according to a third embodiment.

FIG. 25 is a schematic cross-sectional view schematically illustrating the method for adjusting the frequency of the crystal resonator according to the third embodiment.

FIG. 26 is a schematic cross-sectional view corresponding to FIG. 25, which illustrates the frequency adjustment metal film of the crystal resonator according to a variation of the third embodiment.

FIG. 27 is a schematic cross-sectional view schematically illustrating the method for irradiating the frequency adjustment metal film with a laser according to the third embodiment.

FIG. 28(a) and FIG. 28(b) are schematic cross-sectional views schematically illustrating the method for irradiating the frequency adjustment metal film with a laser according to a comparative example of the third embodiment.

FIG. 29 is a schematic cross-sectional view illustrating the method for irradiating the frequency adjustment metal film with a laser according to the third embodiment.

FIG. 30 is a schematic plan view schematically illustrating a variation of a shielding film of the crystal resonator according to the third embodiment.

FIG. 31 is a schematic cross-sectional view corresponding to FIG. 25, which illustrates the method for adjusting the frequency of the crystal resonator according to a variation of the third embodiment.

FIG. 32 is a schematic plan view illustrating the first main surface of the second sealing member of the crystal resonator according to a fourth embodiment.

FIG. 33 is a schematic cross-sectional view schematically illustrating the method for adjusting the frequency of the crystal resonator according to the fourth embodiment.

FIG. 34 is a schematic plan view schematically illustrating the method for irradiating the frequency adjustment metal film with a laser according to the fourth embodiment.

FIG. 35 is a schematic cross-sectional view illustrating the frequency adjustment metal film of the crystal resonator according to the fourth embodiment.

FIG. 36 is a schematic cross-sectional view corresponding to FIG. 35, which illustrates the frequency adjustment metal film of the crystal resonator according to a variation of the fourth embodiment.

FIG. 37 is a schematic cross-sectional view corresponding to FIG. 35, which illustrates the method for adjusting the frequency of the crystal resonator according to a variation of the fourth embodiment.

FIG. 38 is a schematic plan view illustrating the second main surface of the first sealing member of the crystal resonator according to a fifth embodiment.

FIG. 39 is a schematic plan view illustrating the first main surface of the crystal resonator plate according to the fifth embodiment.

FIG. 40 is a schematic plan view illustrating the second main surface of the crystal resonator plate according to the fifth embodiment.

FIG. 41 is a schematic plan view illustrating the first main surface of the second sealing member of the crystal resonator according to the fifth embodiment.

FIG. 42 is a schematic plan view illustrating the second main surface of the second sealing member of the crystal resonator according to the fifth embodiment.

FIG. 43 is a schematic configuration diagram schematically illustrating the configuration of the crystal resonator according to a sixth embodiment.

FIG. 44 is a schematic configuration diagram schematically illustrating the configuration of the crystal resonator according to a variation of the sixth embodiment.

FIG. 45 is a schematic configuration diagram schematically illustrating the configuration of the crystal resonator according to a variation of the sixth embodiment.

FIG. 46 is a schematic configuration diagram schematically illustrating the configuration of the crystal resonator according to a variation of the sixth embodiment.

### MODES FOR CARRYING OUT THE INVENTION

### First Embodiment

Hereinafter, an embodiment of the present invention will be described in detail with reference to the drawings. In the embodiment below, a piezoelectric resonator device to which the present invention is applied is exemplarily shown as a crystal resonator.

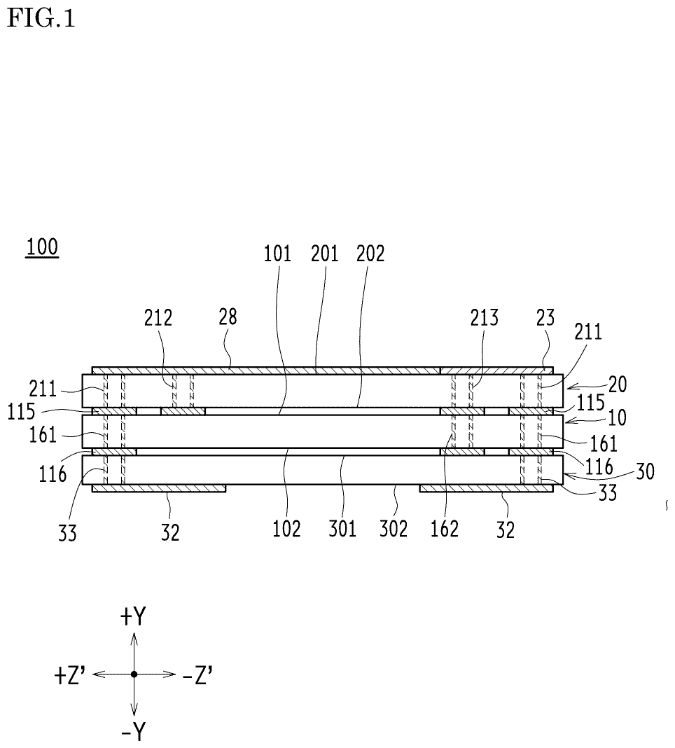

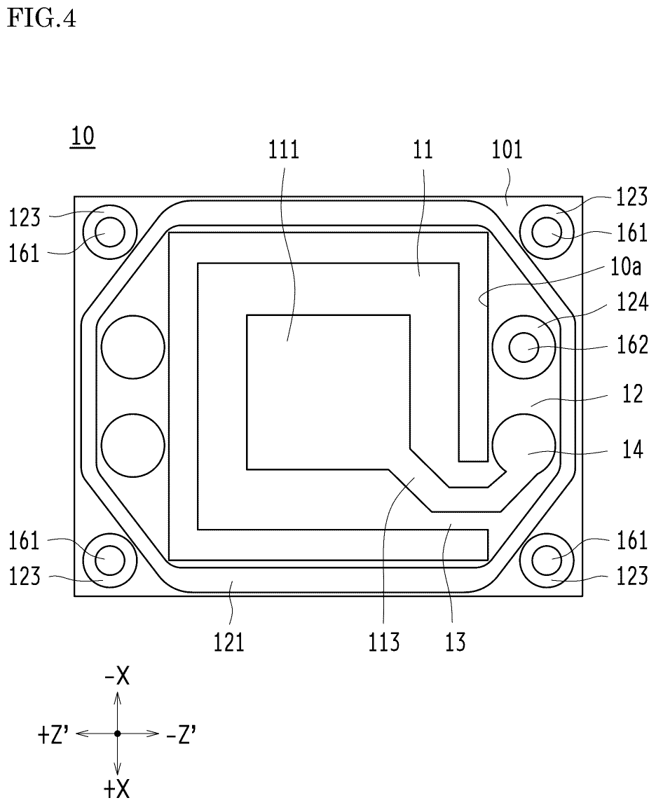

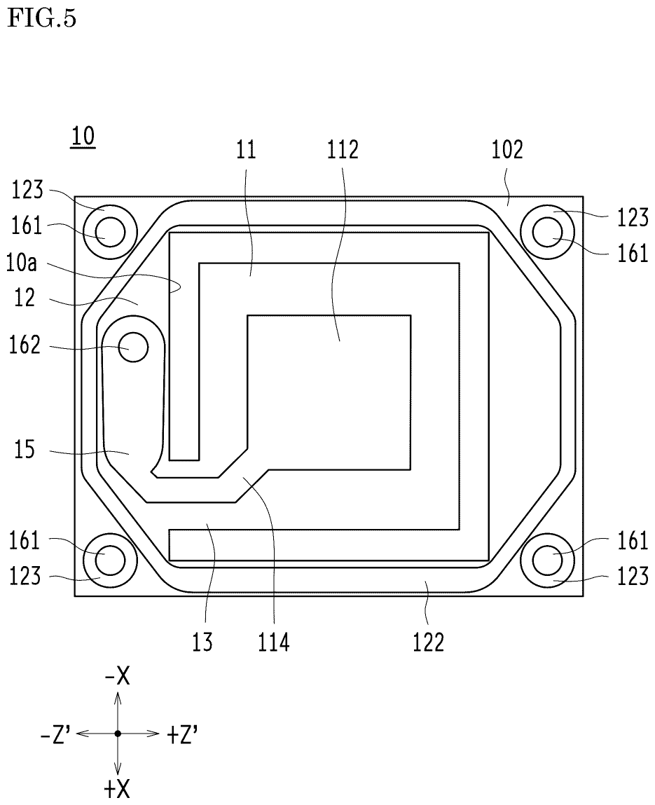

First, a basic configuration of a crystal resonator 100 according to this embodiment is described. As shown in FIG. 1, the crystal resonator 100 includes: a crystal resonator plate (piezoelectric resonator plate) 10; a first sealing member 20; and a second sealing member 30. In this crystal resonator 100, the crystal resonator plate 10 is bonded to the first sealing member 20, and furthermore the crystal resonator plate 10 is bonded to the second sealing member 30. Thus, a package having a sandwich structure is formed so as to have a substantially rectangular parallelepiped shape. That is, in the crystal resonator 100, the first sealing member 20 and the second sealing member 30 are bonded to respective main surfaces of the crystal resonator plate 10, thus an internal space (cavity) of the package is formed. In this internal space, a vibrating part 11 (see FIGS. 4 and 5) is hermetically sealed.

The crystal resonator 100 according to this embodiment has, for example, a package size of 1.0×0.8 mm, which is reduced in size and height. According to the size reduction, no castellation is formed in the package. Through holes are used for conduction between electrodes, as described later. The crystal resonator 100 is electrically connected to an external circuit board (not shown) provided outside via solder.

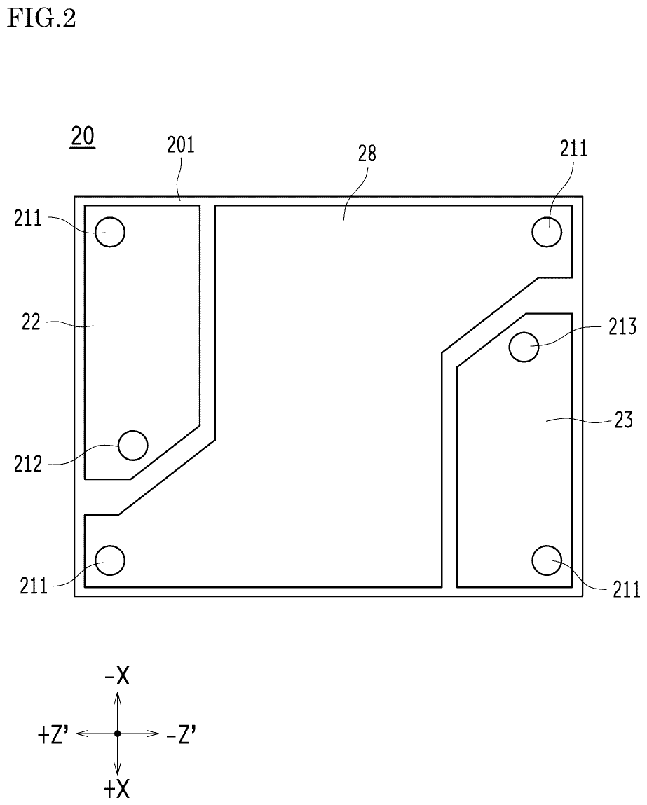

Next, the respective components of the above-described crystal resonator 100 (i.e. the crystal resonator plate 10, the first sealing member 20 and the second sealing member 30) are described with reference to FIGS. 1 to 7. Here, each of the components is described as a single body without being bonded. FIGS. 2 to 7 merely show respective configuration examples of the crystal resonator plate 10, the first sealing member 20 and the second sealing member 30, and thus the present invention is not limited thereto.

The crystal resonator plate 10 according to this embodiment is a piezoelectric substrate made of crystal as shown in FIGS. 4 and 5. Each main surface (i.e. a first main surface 101 and a second main surface 102) is formed as a smooth flat surface by polishing (mirror finishing). In this embodiment, an AT-cut crystal plate that causes thickness shear vibration is used as the crystal resonator plate 10. In the crystal resonator plate 10 shown in FIGS. 4 and 5, each of the main surfaces 101 and 102 of the crystal resonator plate 10 is an XZ′ plane. On this XZ′ plane, the direction parallel to the lateral direction (short side direction) of the crystal resonator plate 10 is the X axis direction, and the direction parallel to the longitudinal direction (long side direction) of the crystal resonator plate 10 is the Z′ axis direction. The AT-cut method is a processing method in which a crystal plate is cut out of synthetic quartz crystal at an angle tilted by 35° 15′ about the X axis from the Z axis, out of the three crystal axes (i.e. an electrical axis (X axis), a mechanical axis (Y axis) and an optical axis (Z axis)) of the synthetic quartz crystal. The X axis of the AT-cut crystal plate equals the crystal axis of the crystal. The Y′ axis and the Z′ axis equal the respective axes that tilt by approximately 35° 15′ from the Y axis and the Z axis out of the crystal axes of the crystal (this cutting angle may be changed to a certain extent within the range in which the frequency temperature characteristics of the AT-cut crystal resonator plate can be adjusted). The Y′ axis direction and the Z′ axis direction correspond to the directions in which the AT-cut crystal is cut out.

A pair of excitation electrodes (i.e. a first excitation electrode 111 and a second excitation electrode 112) is formed, respectively, on the main surfaces 101 and 102 of the crystal resonator plate 10. The crystal resonator plate 10 includes: the vibrating part 11 formed so as to have a substantially rectangular shape; an external frame part 12 surrounding the outer periphery of the vibrating part 11; and a support part (connection part) 13 that supports the vibrating part 11 by connecting the vibrating part 11 to the external frame part 12. That is, the crystal resonator plate 10 has a configuration in which the vibrating part 11, the external frame part 12 and the support part 13 are integrally formed. The support part 13 extends (protrudes) from only one corner part positioned in the +X direction and in the −Z′ direction of the vibrating part 11 to the external frame part 12 in the −Z′ direction. A penetrating part (slit) 10a is formed between the vibrating part 11 and the external frame part 12 so as to penetrate the crystal resonator plate 10 in the thickness direction. In this embodiment, the crystal resonator plate 10 has only one support part 13 to connect the vibrating part 11 to the external frame part 12. The penetrating part 10a is continuously formed so as to surround the outer periphery of the vibrating part 11.

The first excitation electrode 111 is provided on the first main surface 101 side of the vibrating part 11 while the second excitation electrode 112 is provided on the second main surface 102 side of the vibrating part 11. The first excitation electrode 111 and the second excitation electrode 112 are respectively connected to input and output lead-out wirings (i.e. a first lead-out wiring 113 and a second lead-out wiring 114) so that these excitation electrodes are connected to external electrode terminals. The first input lead-out wiring 113 is drawn out from the first excitation electrode 111 and connected to a connection bonding pattern 14 formed on the external frame part 12 via the support part 13. The second output lead-out wiring 114 is drawn out from the second excitation electrode 112 and connected to a connection bonding pattern 15 formed on the external frame part 12 via the support part 13.

Resonator-plate-side sealing parts to bond the crystal resonator plate 10 respectively to the first sealing member 20 and the second sealing member 30 are provided on the respective main surfaces (i.e. the first main surface 101 and the second main surface 102) of the crystal resonator plate 10. As the resonator-plate-side sealing part on the first main surface 101, a resonator-plate-side first bonding pattern 121 is formed. As the resonator-plate-side sealing part on the second main surface 102, a resonator-plate-side second bonding pattern 122 is formed. The resonator-plate-side first bonding pattern 121 and the resonator-plate-side second bonding pattern 122 are each formed on the external frame part 12 so as to have an annular shape in plan view.

Also, as shown in FIGS. 4 and 5, five through holes are formed in the crystal resonator plate 10 so as to penetrate between the first main surface 101 and the second main surface 102. More specifically, four first through holes 161 are respectively disposed in the four corners (corner parts) of the external frame part 12. A second through hole 162 is disposed in the external frame part 12, on one side in the Z′ axis direction relative to the vibrating part 11 (in FIGS. 4 and 5, on the side of the −Z′ direction). Connection bonding patterns 123 are formed on the respective peripheries of the first through holes 161. Also, on the periphery of the second through hole 162, a connection bonding pattern 124 is formed on the first main surface 101 side while the connection bonding pattern 15 is formed on the second main surface 102 side.

In the first through holes 161 and the second through hole 162, through electrodes are respectively formed along a corresponding inner wall surface of the above through holes so as to establish conduction between the electrodes formed on the first main surface 101 and the second main surface 102. Respective center parts of the first through holes 161 and the second through hole 162 are hollow penetrating parts penetrating between the first main surface 101 and the second main surface 102. The outer peripheral edge of the resonator-plate-side first bonding pattern 121 is disposed so as to be adjacent to the outer peripheral edge of the first main surface 101 of the crystal resonator plate 10 (external frame part 12). The outer peripheral edge of the resonator-plate-side second bonding pattern 122 is disposed so as to be adjacent to the outer peripheral edge of the second main surface 102 of the crystal resonator plate 10 (external frame part 12). In this embodiment, the configuration is exemplarily described, in which five through holes are formed so as to penetrate between the first main surface 101 and the second main surface 102. However, the through holes are not necessarily required to be formed. In place of the through holes, a castellation may be used by cutting out a part of the side surface of the first sealing member 20, and attaching an electrode to an inner wall surface of the cut-out region. (In this case, this configuration is also applied to the second sealing member 30).

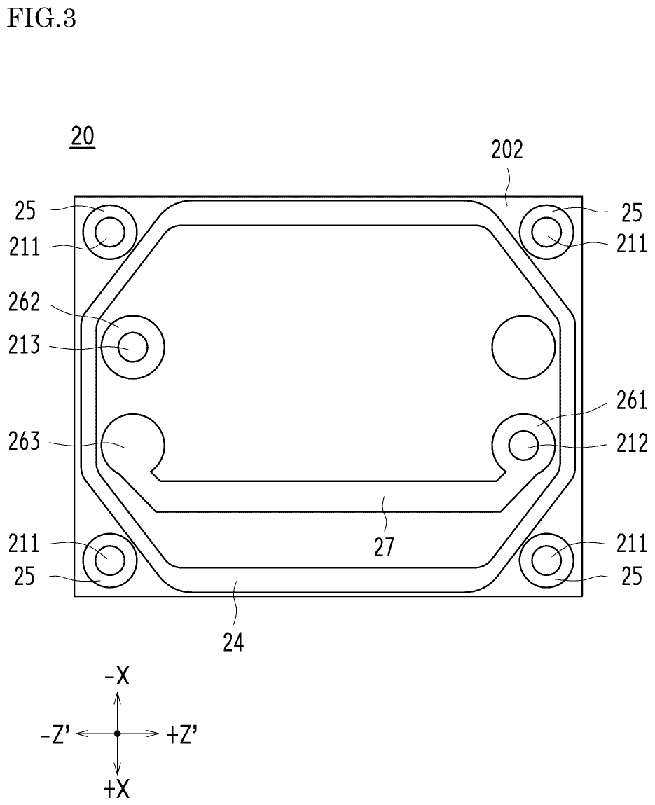

As shown in FIGS. 2 and 3, the first sealing member 20 is a substrate having a rectangular parallelepiped shape that is made of a single AT-cut crystal plate as a transparency material. A second main surface 202 (a surface to be bonded to the crystal resonator plate 10) of the first sealing member 20 is formed as a smooth flat surface by polishing (mirror finishing). By making the first sealing member 20, which does not have the vibrating part, of the AT-cut crystal plate as in the case of the crystal resonator plate 10, it is possible for the first sealing member 20 to have the same coefficient of thermal expansion as the crystal resonator plate 10. Thus, it is possible to prevent thermal deformation of the crystal resonator 100. Furthermore, the respective directions of the X axis, Y axis and Z′ axis of the first sealing member 20 are the same as those of the crystal resonator plate 10.

As shown in FIG. 2, first and second terminals 22 and 23 for wiring and a metal film 28 for shielding (for earth connection) are formed on a first main surface 201 (the outer main surface not facing the crystal resonator plate 10) of the first sealing member 20. The first and the second terminals 22 and 23 for wiring are provided as the wirings for electrically connecting respectively the first and the second excitation electrodes 111 and 112 of the crystal resonator plate 10 to external electrode terminals 32 of the second sealing member 30. The first and the second terminals 22 and 23 are respectively provided on both end parts in the Z′ direction. Specifically, the first terminal 22 is provided on the end part in the +Z′ direction while the second terminal 23 is provided on the end part in the −Z′ direction. The first and the second terminals 22 and 23 are both formed so as to extend in the X axis direction. The first and the second terminals 22 and 23 are each formed so as to have a substantially rectangular shape.

The metal film 28 is disposed between the first terminal 22 and the second terminal 23 at a predetermined distance from both the first terminal 22 and the second terminal 23. The metal film 28 is provided over almost the entire area of the first main surface 201 of the first sealing member 20, except for the area where the first terminal 22 and the second terminal 23 are provided. The metal film 28 is provided so as to cover from the end of the first main surface 201 of the first sealing member 20 in the +X direction to the end thereof in the −X direction.

As shown in FIGS. 2 and 3, six through holes are formed in the first sealing member 20 so as to penetrate between the first main surface 201 and the second main surface 202. More specifically, four third through holes 211 are respectively disposed in the four corners (corner parts) of the first sealing member 20. Fourth and fifth through holes 212 and 213 are disposed respectively in the +Z′ direction and in the −Z′ direction in FIGS. 2 and 3.

In the third through holes 211 and the fourth and the fifth through holes 212 and 213, through electrodes are respectively formed along a corresponding inner wall surface of the above through holes so as to establish conduction between the electrodes formed on the first main surface 201 and the second main surface 202. Respective center parts of the third through holes 211 and the fourth and the fifth through holes 212 and 213 are hollow penetrating parts penetrating between the first main surface 201 and the second main surface 202. The respective through electrodes of the two third through holes 211 and 211 that are diagonally positioned on the first main surface 201 of the first sealing member 20 (i.e. in FIGS. 2 and 3, the third through hole 211 positioned in the corner part in the +X direction and in the +Z′ direction and the third through hole 211 positioned in the corner part in the −X direction and in the −Z′ direction) are electrically connected via the metal film 28. Also, the through electrode of the third through hole 211 positioned in the corner part in the −X direction and in the +Z direction is electrically connected to the through electrode of the fourth through hole 212 via the first terminal 22. Furthermore, the through electrode of the third through hole 211 positioned in the corner part in the +X direction and in the −Z′ direction is electrically connected to the through electrode of the fifth through hole 213 via the second terminal 23.

On the second main surface 202 of the first sealing member 20, a sealing-member-side first bonding pattern 24 is formed as a sealing-member-side first sealing part so as to be bonded to the crystal resonator plate 10. The sealing-member-side first bonding pattern 24 is formed so as to have an annular shape in plan view. On the second main surface 202 of the first sealing member 20, connection bonding patterns 25 are respectively formed on the peripheries of the third through holes 211. A connection bonding pattern 261 is formed on the periphery of the fourth through hole 212, and a connection bonding pattern 262 is formed on the periphery of the fifth through hole 213. Furthermore, a connection bonding pattern 263 is formed on the side opposite to the connection bonding pattern 261 in the long axis direction of the first sealing member 20 (i.e. on the side of the −Z′ direction). The connection bonding pattern 261 and the connection bonding pattern 263 are connected to each other via a wiring pattern 27. The outer peripheral edge of the sealing-member-side first bonding pattern 24 is disposed so as to be adjacent to the outer peripheral edge of the second main surface 202 of the first sealing member 20.

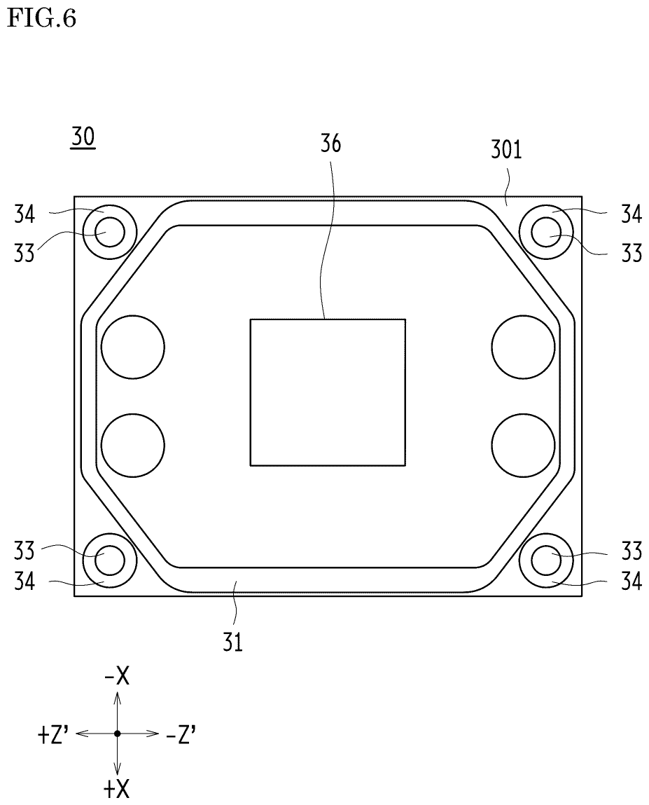

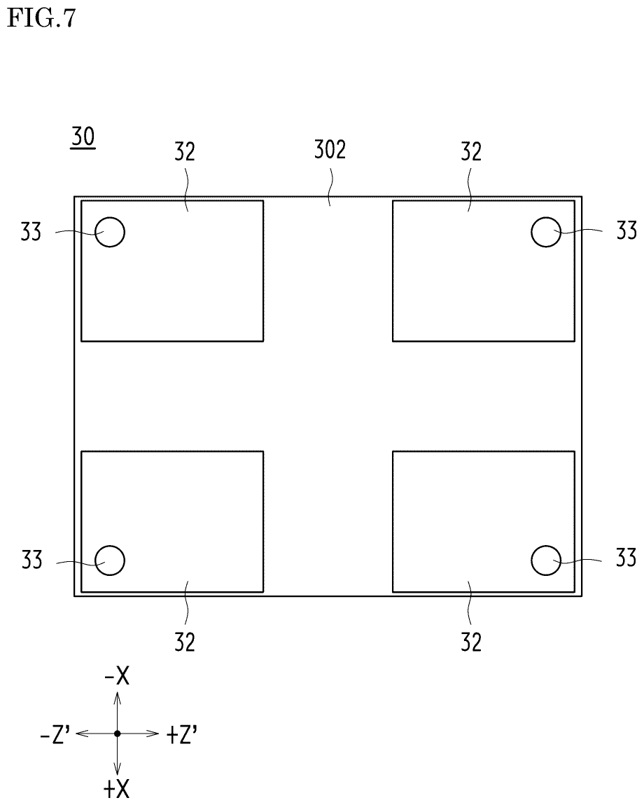

As shown in FIGS. 6 and 7, the second sealing member 30 is a substrate having a rectangular parallelepiped shape that is made of a single AT-cut crystal plate as a transparency material. A first main surface 301 (a surface to be bonded to the crystal resonator plate 10) and a second main surface 302 (an outer main surface not facing the crystal resonator plate 10) of the second sealing member 30 are each formed as a smooth flat surface by polishing (mirror finishing). The second sealing member 30 is also preferably made of an AT-cut crystal plate as in the case of the crystal resonator plate 10, and the respective directions of the X axis, the Y axis and the Z′ axis of the second sealing member 30 are preferably the same as those of the crystal resonator plate 10.

On the first main surface 301 of the second sealing member 30, a sealing-member-side second bonding pattern 31 is formed as a sealing-member-side second sealing part so as to be bonded to the crystal resonator plate 10. The sealing-member-side second bonding pattern 31 is formed so as to have an annular shape in plan view. The outer peripheral edge of the sealing-member-side second bonding pattern 31 is disposed so as to be adjacent to the outer peripheral edge of the first main surface 301 of the second sealing member 30.

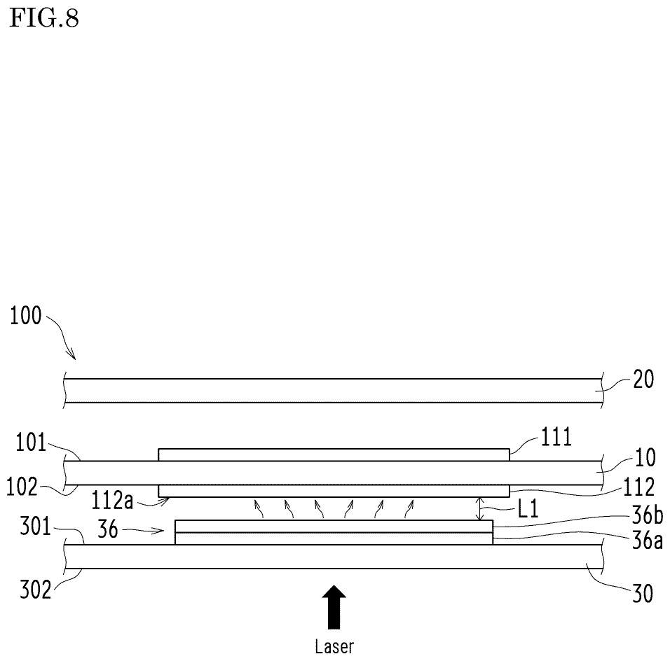

Also, on the first main surface 301 of the second sealing member 30, a frequency adjustment metal film 36 is formed so as to be used to adjust the frequency of the crystal resonator 100. The frequency adjustment metal film 36 has a two-layer structure made of two kinds of metals having different melting temperatures (melting points), and is constituted of a base metal layer 36a and a metal layer 36b laminated on the base metal layer 36a as shown in FIG. 8. The base metal layer 36a has a thickness of, for example, 50 nm while the metal layer 36b has a thickness of, for example, 100 nm. The thickness of the base metal layer 36a is preferably 50 to 500 nm, and the thickness of the metal layer 36b is preferably 100 to 500 nm. It is not preferable that the thickness of the base metal layer 36a is less than 50 nm because such a base metal layer 36a cannot withstand the irradiation with the laser. Also, it is not preferable that the thickness of the base metal layer 36a is more than 500 nm because in such a base metal layer 36a, a wafer warps and the production efficiency is decreased due to layer thickness. It is not preferable that the thickness of the metal layer 36b is less than 100 nm because such a metal layer 36b cannot withstand the irradiation with the laser. Also, it is not preferable that the thickness of the metal layer 36b is more than 500 nm because in such a metal layer 36b, a wafer warps and the production efficiency is decreased due to layer thickness.

In the frequency adjustment metal film 36, the melting temperature of the base metal layer 36a is set to be higher than the melting temperature of the metal layer 36b, the reason for which is explained later. Furthermore, it is preferable that the difference between the melting temperature of the base metal layer 36a and the melting temperature of the metal layer 36b is not less than 1500 K. The metal layer 36b is made of the same material as that of the second excitation electrode 112 (for example, Au), and in this case the melting temperature of the Au is 1064 K. Thus, it is possible to use, for example, as the material of the base metal layer 36a, any one of: W (tungsten: melting temperature of 3387 K); Mo (molybdenum: melting temperature of 2623 K); Ta (tantalum: melting temperature of 3020 K); and Re (rhenium: melting temperature of 3186 K).

The frequency adjustment metal film 36 is disposed so as to face the second excitation electrode 112 at a predetermined interval. The distance L1 between the second excitation electrode 112 and the frequency adjustment metal film 36 in the vertical direction (the Y axis direction) is 2 to 200 μm.

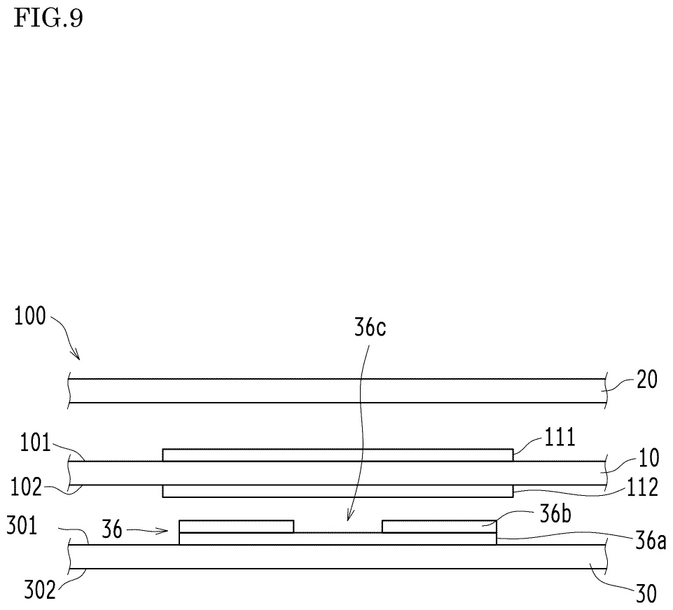

The frequency adjustment metal film 36 is formed in a substantially rectangular shape in plan view. The frequency adjustment metal film 36 is slightly smaller than the second excitation electrode 112 so that the outer peripheral edge of the frequency adjustment metal film 36 is located in the inside of the outer peripheral edge of the second excitation electrode 112 in plan view. Also, at least a part of the base metal layer 36a is not covered by the metal layer 36b but is exposed, and thus, a step part 36c (FIG. 9) is formed in the inside of the frequency adjustment metal film 36. With the above configuration, even when the vibrating part 11 is bent by an external impact so that the exposed part of the base metal layer 36a of the frequency adjustment metal film 36 comes into contact with the second excitation electrode 112, adhesion (sticking) of the base metal layer 36a to the second excitation electrode 112 can be prevented.

The first and the second main surfaces 301 and 302 of the second sealing member 30 are each formed as a smooth flat surface by polishing. The arithmetic average roughness Ra of the first and the second main surfaces 301 and 302 is 1 nm or less. Also, the arithmetic average roughness Ra of the surface of the metal layer 36b of the frequency adjustment metal film 36 is 3 nm or less.

On the second main surface 302 of the second sealing member 30, four external electrode terminals 32 are formed, which are electrically connected to an external circuit board provided outside the crystal resonator 100. The external electrode terminals 32 are respectively located on four corners (corner parts) on the second main surface 302 of the second sealing member 30.

As shown in FIGS. 6 and 7, four through holes are formed in the second sealing member 30 so as to penetrate between the first main surface 301 and the second main surface 302. More specifically, four sixth through holes 33 are respectively disposed in the four corners (corner parts) of the second sealing member 30. In the sixth through holes 33, through electrodes are respectively formed along a corresponding inner wall surface of the sixth through holes 33 so as to establish conduction between the electrodes formed on the first main surface 301 and the second main surface 302. In this way, the respective electrodes formed on the first main surface 301 are electrically conducted to the external electrode terminals 32 formed on the second main surface 302 via the through electrodes formed along the inner wall surfaces of the sixth through holes 33. Also, respective central parts of the sixth through holes 33 are hollow penetrating parts penetrating between the first main surface 301 and the second main surface 302. On the first main surface 301 of the second sealing member 30, connection bonding patterns 34 are respectively formed on the peripheries of the sixth through holes 33.

In the crystal resonator 100 including the crystal resonator plate 10, the first sealing member 20 and the second sealing member 30 as described above, the crystal resonator plate 10 and the first sealing member 20 are subjected to the diffusion bonding in a state in which the resonator-plate-side first bonding pattern 121 and the sealing-member-side first bonding pattern 24 are superimposed on each other, and the crystal resonator plate 10 and the second sealing member 30 are subjected to the diffusion bonding in a state in which the resonator-plate-side second bonding pattern 122 and the sealing-member-side second bonding pattern 31 are superimposed on each other, thus, the package having the sandwich structure as shown in FIG. 1 is produced. Accordingly, the internal space of the package, i.e. the space to house the vibrating part 11 is hermetically sealed.

In this case, the respective connection bonding patterns as described above are also subjected to the diffusion bonding in a state in which they are each superimposed on the corresponding connection bonding pattern. Such bonding between the connection bonding patterns allows electrical conduction of the first excitation electrode 111, the second excitation electrode 112 and the external electrode terminals 32 of the crystal resonator 100. More specifically, the first excitation electrode 111 is connected to the external electrode terminal 32 via the first lead-out wiring 113, the wiring pattern 27, the fourth through hole 212, the first terminal 22, the third through hole 211, the first through hole 161 and the sixth through hole 33 in this order. The second excitation electrode 112 is connected to the external electrode terminal 32 via the second lead-out wiring 114, the second through hole 162, the fifth through hole 213, the second terminal 23, the third through hole 211, the first through hole 161 and the sixth through hole 33 in this order. Also, the metal film 28 is earth-connected (i.e. ground connection, using parts of the external electrode terminals 32) via the third through holes 211, the first through holes 161 and the sixth through holes 33 in this order.

In the crystal resonator 100, the bonding patterns are each preferably made of a plurality of layers laminated on the crystal plate, specifically, a Ti (titanium) layer and a Au (gold) layer deposited, by vapor deposition or sputtering, in this order from the lowermost layer side. Also, the other wirings and electrodes formed on the crystal resonator 100 each preferably have the same configuration as the bonding patterns, which leads to patterning of the bonding patterns, wirings and the electrodes at the same time.

In the above-described crystal resonator 100, sealing parts (seal paths) 115 and 116 that hermetically seal the vibrating part 11 of the crystal resonator plate 10 are formed so as to have an annular shape in plan view. The seal path 115 is formed by the diffusion bonding (Au—Au bonding) of the resonator-plate-side first bonding pattern 121 and the sealing-member-side first bonding pattern 24 as described above. The outer edge and the inner edge of the seal path 115 both have a substantially octagonal shape. In the same way, the seal path 116 is formed by the diffusion bonding (Au—Au bonding) of the resonator-plate-side second bonding pattern 122 and the sealing-member-side second bonding pattern 31 as described above. The outer edge and the inner edge of the seal path 116 both have a substantially octagonal shape.

Here, a description is given on the frequency adjustment method of the crystal resonator 100 according to this embodiment with reference to FIG. 8. The frequency adjustment in this embodiment is a step of adjusting the mass of the second excitation electrode 112 of the vibrating part 11 of the crystal resonator plate 10 so as to adjust the oscillation frequency to a desired value. The frequency adjustment is performed to each crystal resonator 100 in a state of a wafer in the manufacturing process of the crystal resonator 100. Alternatively, the frequency adjustment may be performed to the crystal resonator 100 as each individual piece processed from the wafer.

As specifically shown in FIG. 8, the frequency adjustment metal film 36 is irradiated with a laser from the outside of the second sealing member 30 so that the laser penetrates the interior of the second sealing member 30 and heats the base metal layer 36a. Thus, at least part of the metal layer 36b is melted and evaporated (turned into gas), and the evaporated metal is adhered to the second excitation electrode 112. In this way, the frequency adjustment is performed. That is, the metal layer 36b disposed on the base metal layer 36a is melted and evaporated by the laser, and the evaporated metal is adhered to the second excitation electrode 112 to increase the mass of the second excitation electrode 112. Thus, the frequency is shifted to the lower side.

The laser is emitted perpendicularly to the second sealing member 30. As the laser, a visible light laser is used, which can penetrate the second sealing member 30 made of crystal. In particular, it is possible to use a green laser with the wavelength of about 532 nm (however, the wavelength of the laser is not limited to 532 nm). The value of the laser power is adjusted so as not to penetrate the base metal layer 36a of the frequency adjustment metal film 36. When the base metal layer 36a is heated by the laser, the metal layer 36b disposed on the base metal layer 36a is also heated. As described above, the melting temperature of the base metal layer 36a is higher than the melting temperature of the metal layer 36b. Thus, when the base metal layer 36a is heated so as to have a temperature higher than the melting temperature of the metal layer 36b, the metal layer 36b is melted, and part of the melted metal layer 36b is evaporated. Since the inside of the crystal resonator 100 is in a vacuum state, the evaporated metal moves upward substantially linearly and when the evaporated metal reaches a surface 112a of the second excitation electrode 112, it is cooled by the surface 112a of the second excitation electrode 112 so as to be solidified. In this way, the metal evaporated from the frequency adjustment metal film 36 is adhered to the surface 112a of the second excitation electrode 112.

The metal layer 36b may have a multi-layer structure made of a plurality of metal layers. In this case, it is possible to use, as the material of the metal layer 36b apart from the Au: Ag (silver: melting temperature of 962 K); and Al (aluminum: melting temperature of 660 K). When the metal layer 36b has the multi-layer structure, only the uppermost metal layer is needed to be made of the same material as that of the second excitation electrode 112 (for example, Au). Also, the base metal layer 36a may also have a multi-layer structure made of a plurality of metal layers. In this case, it is preferable that the metal layer having a higher melting temperature (for example, a W layer) is disposed as a lower layer (i.e. disposed closer to the second sealing member 30) and the metal layer having a lower melting temperature (for example, a Mo layer) is disposed as an upper layer (i.e. disposed closer to the metal layer 36b).

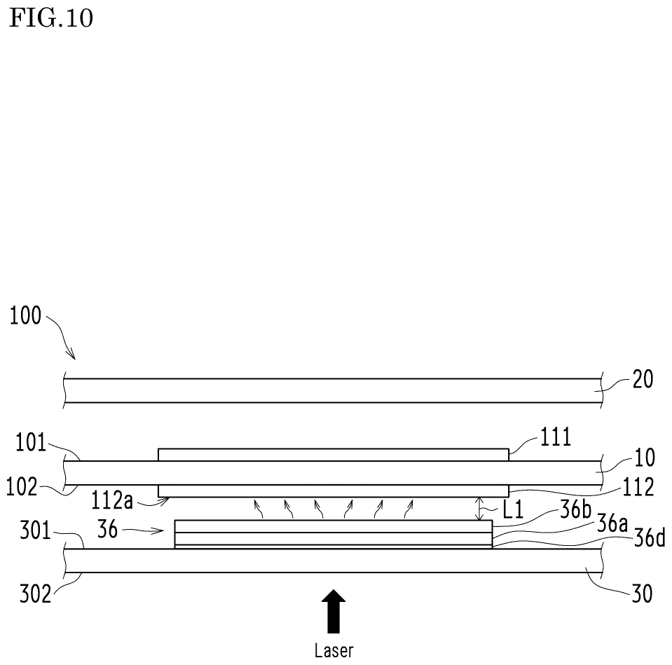

Also, an auxiliary metal layer 36d (see FIG. 10) may be formed between the base metal layer 36a and the second sealing member 30. In this case, it is possible to improve adhesion of the frequency adjustment metal film 36 to the second sealing member 30 by using, as the material of the auxiliary metal layer 36d, a metal having excellent adhesion to the crystal such as Ti (titanium), Cr (chromium), and Ni (nickel). The auxiliary metal layer 36d is required to have a melting temperature sufficiently higher than the melting temperature of the metal layer 36b, however, the difference between the melting temperature of the auxiliary metal layer 36d and the melting temperature of the metal layer 36b is not required to be 1500 K or more, unlike the case of the base metal layer 36a. For example, when the auxiliary metal layer 36d is made of Ti and the metal layer 36b is made of Au, the melting temperature of the Ti is 1672 K, and thus the difference in the melting temperature between the Ti and the Au is about 600 K. Even when the auxiliary metal layer 36d is slightly melted by the laser irradiation at the time of the frequency adjustment, it is possible to prevent the melted auxiliary metal layer 36d from scattering to the second excitation electrode 112, because of the existence of the base metal layer 36a on the auxiliary metal layer 36d.

Also, the auxiliary metal layer 36d melted by the heat of the laser irradiation may be diffused on the base metal layer 36a as the upper layer, which may cause decrease of the melting temperature of the base metal layer 36a. In order to address this problem, the film thickness of the auxiliary metal layer 36d is made thin compared to the film thickness of the base metal layer 36a. In this way, it is possible to perform the laser irradiation without melting the base metal layer 36a (i.e. to evaporate only the metal layer 36b).

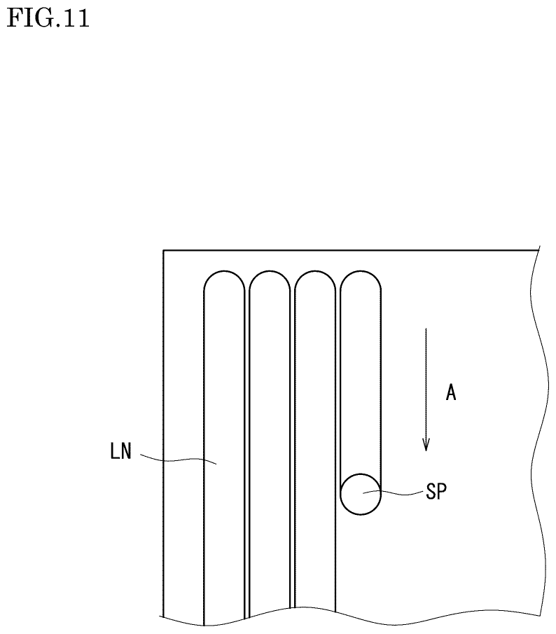

As shown in FIG. 11, the emission of the laser can be performed to a desired region of the base metal layer 36a by arranging irradiation lines LN made by sweeping the laser spot SP in parallel with each other. In this case, it is preferable that the sweep direction (direction indicated by the arrow A) of the laser spot SP is the same for all the irradiation lines LN. Furthermore, it is preferable that the irradiation lines LN adjacent to each other does not overlap in the width direction of the lines (i.e. in the direction orthogonal to the sweep direction). Also, it is preferable that the sweep of the laser spot SP is performed multiple times repeatedly to each irradiation line LN. Like this, it is preferable that after the laser sweep has been performed multiple times to one irradiation line LN, the laser sweep is performed to the next irradiation line LN.

It is possible to control the mass of the metal that is adhered to the second excitation electrode 112 by controlling the number of pulses, the sweep distance, the number of sweeps and the like of the laser emitted to the base metal layer 36a, which leads to control of the amount of the frequency adjustment. For example, by continuously irradiating with the laser whose power and pulse interval are reduced, the base metal layer 36a can be efficiently heated to evaporate only the metal layer 36b. In this case, it is possible to obtain the amount of the frequency adjustment according to the sweep distance of the laser, which leads to the frequency adjustment with a high accuracy.

With the frequency adjustment method of the crystal resonator 100 in this embodiment, the metal layer 36b laminated on the base metal layer 36a is melted and evaporated, and the evaporated metal is adhered to the second excitation electrode 112 to increase the mass of the second excitation electrode 112. Thus, the frequency can be shifted to the lower side. In this case, by controlling the number of pulses, the sweep distance and the like of the laser, it is possible to obtain the desired amount of the frequency adjustment. Also, by preventing the laser from penetrating the frequency adjustment metal film 36, it is possible to avoid damaging the second excitation electrode 112. Therefore, it is possible to perform the frequency adjustment without considerably degrading the characteristics of the crystal resonator 100 even after sealing the vibrating part 11 of the crystal resonator plate 10 by the first and the second sealing members 20 and 30.

In this embodiment, the laser is emitted so as not to penetrate the base metal layer 36a. Since the laser does not penetrate the frequency adjustment metal film 36, it is possible to more reliably avoid damaging the second excitation electrode 112. Therefore, it is possible to easily perform the frequency adjustment without considerably degrading the characteristics of the crystal resonator 100 even after sealing the vibrating part 11 of the crystal resonator plate 10 by the first and the second sealing members 20 and 30.

In this embodiment, the difference between the melting temperature of the base metal layer 36a and the melting temperature of the metal layer 36b is not less than 1500 K. By heating, by the laser irradiation, the base metal layer 36a so as to have a temperature in the range from the melting temperature or more of the metal layer 36b to the melting temperature or less of the base metal layer 36a, only the metal layer 36b is melted while the base metal layer 36a is not melted. Thus, part of the melted metal can be evaporated. The evaporated metal is adhered to the second excitation electrode 112 to increase the mass of the second excitation electrode 112, which shifts the frequency to the lower side. Therefore, it is possible to easily perform the frequency adjustment without considerably degrading the characteristics of the crystal resonator 100 even after sealing the vibrating part 11 of the crystal resonator plate 10 by the first and the second sealing members 20 and 30. Note that even when the melting temperature of the base metal layer 36a is higher than the melting temperature of the metal layer 36b, if the difference between the respective melting temperatures is small, it is difficult to melt only the metal layer 36b, and the base metal layer 36a may be simultaneously melted.

In this embodiment, the first main surface 301 and the second main surface 302 opposite to the first main surface 301, of the second sealing member 30 are both formed as a smooth flat surface. Thus, it is possible to prevent laser reflection and laser refraction when the laser enters the second main surface 302 of the second sealing member 30 and when the laser exits from the first main surface 301 of the second sealing member 30, which leads to reduction in energy loss of the laser. Therefore, it is possible to perform the frequency adjustment with a high accuracy according to the number of pulses, the sweep distance, the number of sweeps and the like of the laser even after sealing the vibrating part 11 of the crystal resonator plate 10 by the first and the second sealing members 20 and 30.

Also, the metal layer 36b is made of Au (gold) as in the case of the second excitation electrode 112, which means that the metal layer 36b is made of the same material as that of the second excitation electrode 112. Thus, the characteristics before the frequency adjustment do not change after the frequency adjustment. In this way, it is possible to prevent the characteristics of the crystal resonator 100 from changing after the sealing.

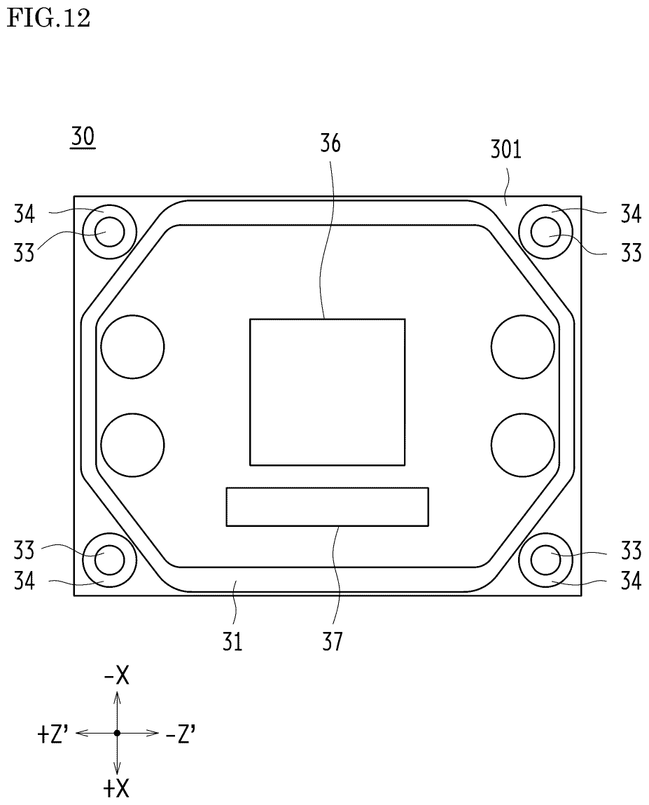

The base metal layer 36a is made of W (tungsten) or the like. Thus, by causing the base metal layer 36a that is exposed to the internal space of the crystal resonator 100 to function as a getter material, gas generated in the internal space of the crystal resonator 100 can be captured by the base metal layer 36a. Here, a metal layer (for example, a W layer) 37 that is the same as the base metal layer 36a may be formed as a separate layer on a region other than the region where the base metal layer 36a is located (see FIG. 12), so as to cause the metal layer 37 to function as a getter material. In this case, the metal layer 37 is preferably formed on the region not facing the second excitation electrode 112.

As the laser, the visible light laser is, for example, used, which has low absorptivity and high transmittance with respect to the second sealing member 30 made of crystal or glass. This type of laser is suitable for the frequency adjustment, because it can prevent loss of power and damage to the second sealing member 30.

Also, since the space in which the vibrating part 11 of the crystal resonator plate 10 is sealed is in a vacuum state, the evaporated metal can be substantially linearly moved, which reduces scatter to the surroundings. Furthermore, it is possible to adhere the evaporated metal to the second excitation electrode 112 without lowering the temperature of the evaporated metal.

In this embodiment, the distance L1 between the second excitation electrode 112 and the frequency adjustment metal film 36 in the vertical direction is 2 to 200 μm. In this way, since the distance L1 between the second excitation electrode 112 and the frequency adjustment metal film 36 is extremely small, it is possible to substantially linearly move the metal that is evaporated from the frequency adjustment metal film 36 so that the evaporated metal is prevented from scattering to the surroundings. Thus, the evaporated metal can be adhered reliably to the second excitation electrode 112, and accordingly, it is possible to easily perform the frequency adjustment with a high accuracy even after sealing the vibrating part 11 of the crystal resonator plate 10 by the first and the second sealing members 20 and 30.

Also, since the outer peripheral edge of the frequency adjustment metal film 36 is located in the inside of the outer peripheral edge of the second excitation electrode 112 in plan view, even when the vibrating part 11 is bent by an external impact so that the exposed part of the base metal layer 36a of the frequency adjustment metal film 36 comes into contact with the second excitation electrode 112, adhesion of the base metal layer 36a to the second excitation electrode 112 can be prevented. Furthermore, it is possible to prevent the metal evaporated from the frequency adjustment metal film 36 from scattering outside the second excitation electrode 112, which results in reliable adhesion of the evaporated metal to the second excitation electrode 112. Therefore, it is possible to easily perform the frequency adjustment with a high accuracy even after sealing the vibrating part 11 of the crystal resonator plate 10 by the first and the second sealing members 20 and 30.

In this embodiment, the crystal resonator 100 includes the first sealing member 20 that covers the first main surface of the vibrating part 11 of the crystal resonator plate 10 and the second sealing member 30 that covers the second main surface of the vibrating part 11 of the crystal resonator plate 10. The first sealing member 20 is bonded to the crystal resonator plate 10, and also the second sealing member 30 is bonded to the crystal resonator plate 10. Thus, the vibrating part 11 of the crystal resonator plate 10 is hermetically sealed. The first sealing member 20 and the second sealing member 30 are each made of crystal. Like this, when the crystal resonator 100 having the three-layer structure is used, it is possible to make the crystal resonator 100 smaller and thinner. And in such a crystal resonator 100 made smaller and thinner, it is possible to perform the frequency adjustment with a high accuracy even after sealing the vibrating part 11 of the crystal resonator plate 10 by the first and the second sealing members 20 and 30.

In the crystal resonator 100 in this embodiment as described above, the frequency adjustment metal film 36 is formed on the first main surface 301 of the second sealing member 30, which faces the second excitation electrode 112. At least a part of the base metal layer 36a of the frequency adjustment metal film 36 is not covered by the metal layer 36b but is exposed. With this configuration, by causing the exposed base metal layer 36a to function as a getter material, gas generated in the internal space of the crystal resonator 100 can be captured by the base metal layer 36a. Thus, it is possible to reduce long time changes of the frequency of the crystal resonator 100 caused by generation of gas.

Since the crystal resonator plate 10 has a configuration including the vibrating part 11 and the external frame part 12 surrounding the vibrating part 11, it is possible to make the distance L1 between the second excitation electrode 112 and the frequency adjustment metal film 36 extremely small compared to the configuration in which the sealing member is bonded to the base using adhesive. Accordingly, it is possible to perform the frequency adjustment with a high accuracy as described above.

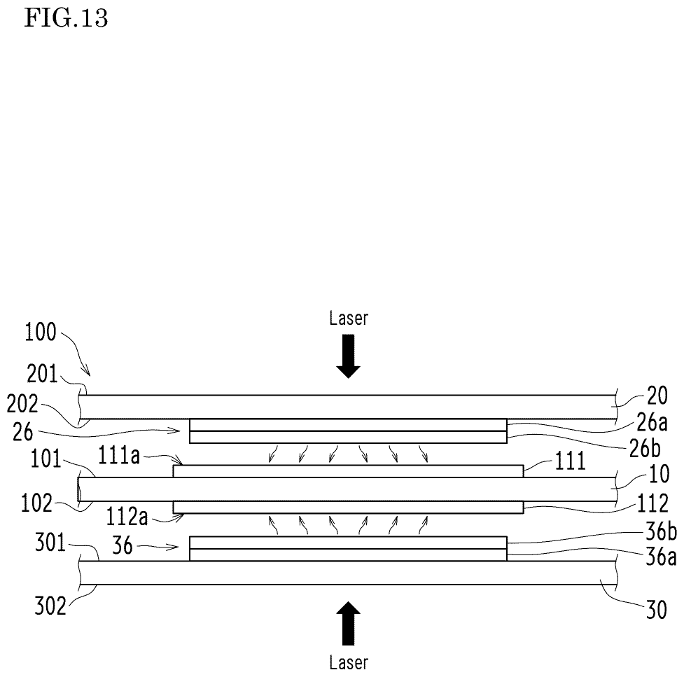

In the above-described embodiment, the frequency adjustment metal film 36 is formed on the first main surface 301 of the second sealing member 30, which faces the second excitation electrode 112. However, the frequency adjustment metal film is not necessarily required to be formed on the second sealing member 30, and it may be formed on the second main surface 202 of the first sealing member 20, which faces the first excitation electrode 111. Alternatively, as shown in FIG. 13, a frequency adjustment metal film 26 may be formed on the second main surface 202 of the first sealing member 20 while the frequency adjustment metal film 36 is formed on the first main surface 301 of the second sealing member 30. The frequency adjustment metal film 26 on the first sealing member 20 has the same configuration as that of the frequency adjustment metal film 36 on the second sealing member 30 in the above-described embodiment. That is, the frequency adjustment metal film 26 is constituted of a base metal layer 26a made of, for example, W (tungsten) and a metal layer 26b made of the same material as the first excitation electrode 111 (for example, Au) that is laminated on the base metal layer 26a.

With a variation shown in FIG. 13, the frequency adjustment can be performed using both the frequency adjustment metal films 26 and 36. Thus, by also irradiating the frequency adjustment metal film 26 with the laser from the side of the first sealing member 20 of the crystal resonator 100, it is possible to perform the frequency adjustment on two sides, i.e. the side of the first sealing member 20 and the side of the second sealing member 30. In this case, the frequency adjustment may be simultaneously performed on the two sides of the first sealing member 20 and the second sealing member 30. Alternatively, the frequency adjustment may be performed on one side at a time in order.

In the above-described embodiment, the frequency adjustment is performed using the visible light laser. However, the frequency adjustment may be performed using another beam such as an electron beam. In this case, it is possible to obtain the desired amount of the frequency adjustment by controlling the beam power, the irradiation time and the like.

In the above-described embodiment, the step part 36c is formed in the center part of the frequency adjustment metal film 36 (see FIG. 9) so as to expose the base metal layer 36a. However, the step part 36c may be formed in at least a part of the frequency adjustment metal film 36. Also, the base metal layer 36a may be exposed at a part other than the outer peripheral edge, provided that the part is not irradiated with the laser.

In the above-described embodiment, the internal space of the crystal resonator 100 is in a vacuum state. However, low-pressure nitrogen or argon may be enclosed in the internal space of the crystal resonator 100.

In the above-described embodiment, the crystal resonator plate 10 is made of an AT-cut crystal plate. However, another type of crystal plate may be used. Also in the above-described embodiment, the vibrating part 11 of the crystal resonator plate 10 has a rectangle shape. However, the vibrating part may have a tuning fork shape.

In the above-described embodiment, the first sealing member 20 and the second sealing member 30 are each made of a crystal plate. However, the first sealing member 20 and the second sealing member 30 may be made of, for example, glass. In this case, an infrared laser may be used, which can penetrate the first sealing member 20 and the second sealing member 30. As the infrared laser, a YAG laser with the wavelength of about 1064 nm can be used. Furthermore, only parts of the first sealing member 20 and the second sealing member 30 may be made of the transparency material such as crystal and glass.

In the above-described embodiment, the crystal resonator plate 10 has only one support part 13 to connect the vibrating part 11 to the external frame part 12. However, two or more support parts 13 may be provided. Also in the above-described embodiment, the penetrating part 10a is provided between the vibrating part 11 and the external frame part 12 so as to penetrate the crystal resonator plate 10 in the thickness direction. However, the crystal resonator plate not having the penetrating part may be used. Also in the above-described embodiment, the crystal resonator plate 10 with the frame body is used, which is provided with the vibrating part 11 and the external frame part 12 surrounding the vibrating part 11. However, the crystal resonator plate not having the external frame part may be used.

### Second Embodiment

The essential configuration of the crystal resonator 100 according to this embodiment is almost the same as the configuration according to the first embodiment, but only the shape of the frequency adjustment metal film 36 formed on the first main surface 301 of the second sealing member 30 is different. Hereinafter, the description is omitted on the same configuration as that of the first embodiment, and only the characteristic features of this embodiment will be described.

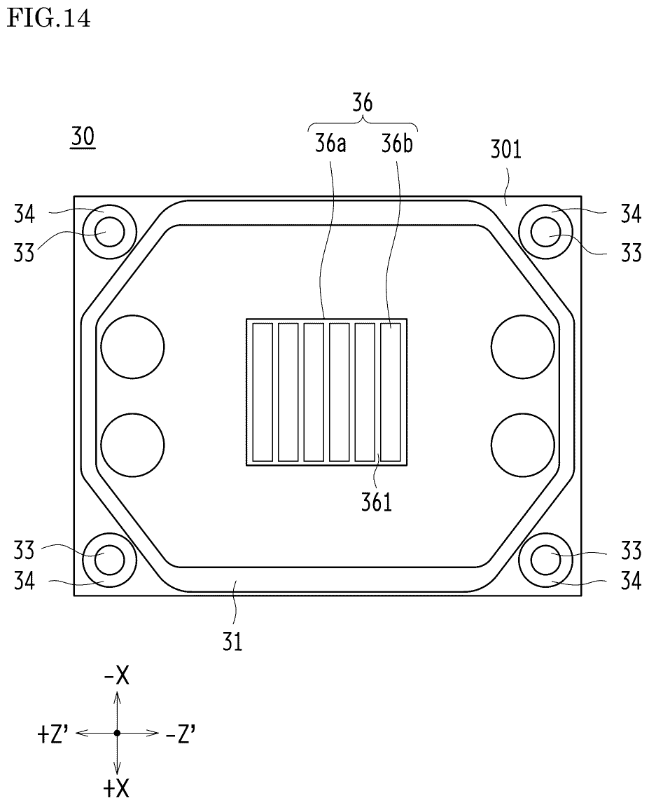

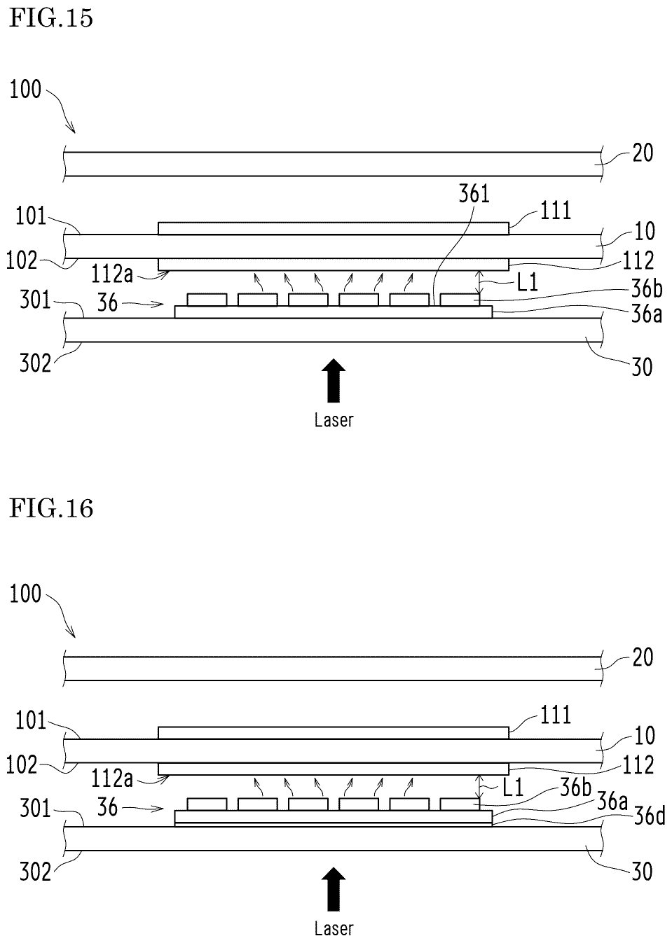

FIG. 14 is a schematic plan view illustrating the first main surface 301 of the second sealing member 30 of the crystal resonator 100 according to this embodiment. FIG. 15 is a schematic cross-sectional view schematically illustrating the method for adjusting the frequency of the crystal resonator 100 according to this embodiment. As shown in FIGS. 14 and 15, in this embodiment also, the frequency adjustment metal film 36 has a two-layer structure made of two kinds of metals having different melting temperatures (melting points), and is constituted of the base metal layer 36a and the metal layer 36b laminated on the base metal layer 36a. However, the metal layer 36b is not formed to cover the entire of the base metal layer 36a. At least a part of the base metal layer 36a is an exposed part 361 that is not covered by the metal layer 36b but is exposed.

In the example shown in FIG. 15, the metal layer 36b is formed in a stripe pattern on the base metal layer 36a, and a gap between the adjacent stripes of the metal layer 36b is the exposed part 361. In other words, the metal layer 36b and the exposed part 361 are formed alternately so as to make the stripes on the surface of the frequency adjustment metal film 36. The exposed part 361 is not limited to the gap between the adjacent stripes of the metal layer 36b, but may be an outer peripheral edge of the frequency adjustment metal film 36 (see FIG. 14). In this embodiment, the favorable conditions (i.e. thickness, material, melting temperature and the like) of the frequency adjustment metal film 36 other than the shape are the same as those in the first embodiment. Also, similarly to the variation of the first embodiment shown in FIG. 10, the auxiliary metal layer 36d may be formed between the base metal layer 36a and the second sealing member 30 (see FIG. 16).

Here, a description is given on the frequency adjustment method of the crystal resonator 100 according to this embodiment. Since the frequency adjustment method of this embodiment is similar to the frequency adjustment method described in the first embodiment, only different points are described while the same points are omitted.

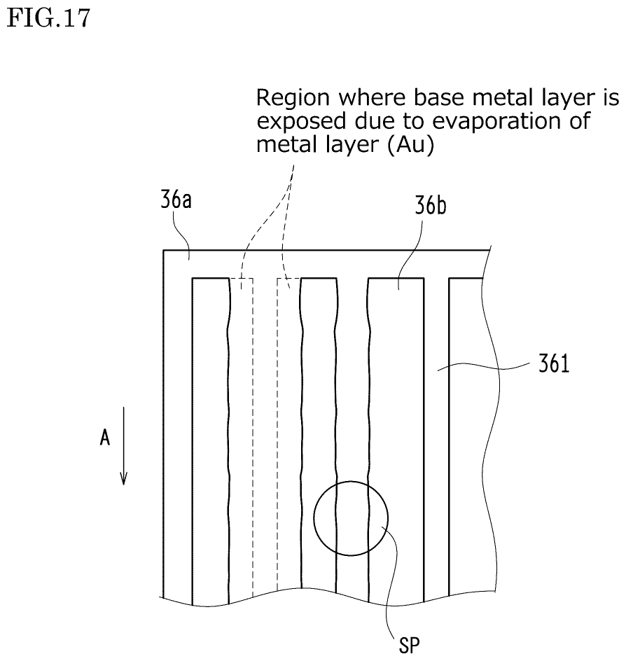

In this embodiment shown in FIG. 17, the frequency adjustment metal film 36 is irradiated by linearly emitting and sweeping the laser spot SP. At this time, the laser sweep is performed such that at least a part of the laser spot SP includes the exposed part 361. In the example shown in FIG. 17, the metal layer 36b and the exposed part 361 are formed alternately so as to make the stripes on the frequency adjustment metal film 36, and the laser sweep is performed in the longitudinal direction (direction indicated by arrow A in FIG. 17) of the linear exposed part 361. In this case, the line width of the exposed part 361 is set to be smaller than the diameter (irradiation diameter) of the laser spot SP. Thus, it is possible to heat respective sides of adjacent lines of the metal layer 36b by both sides of the laser spot SP that is swept. Also, the sweep of the laser spot SP is performed multiple times repeatedly to each irradiation line, and after the laser sweep has been performed multiple times to one irradiation line, the laser sweep is performed to the next irradiation line. At this time, the respective irradiation lines do not interfere with each other (i.e. do not overlap) in plan view.

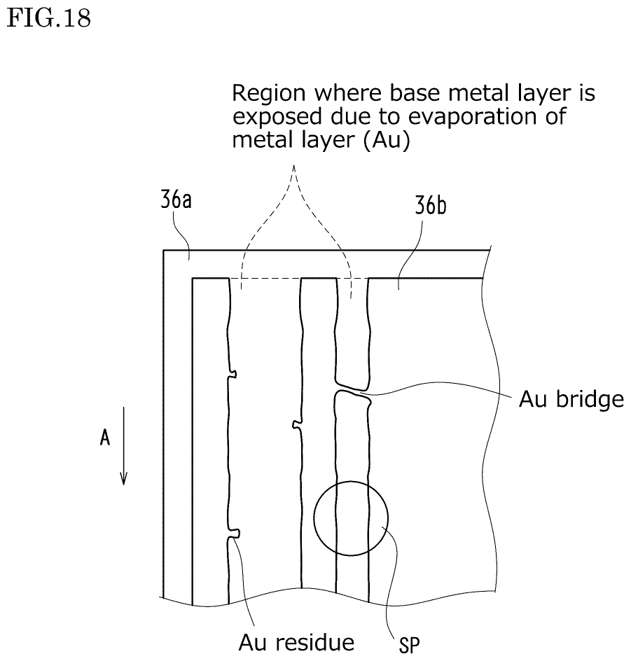

As described above, at the time of the frequency adjustment of the crystal resonator 100, the laser sweep is performed such that at least a part of the laser spot SP includes the exposed part 361. Here, the reason is explained. FIG. 18 is a schematic plan view schematically illustrating the method for irradiating the frequency adjustment metal film 36 with a laser as a comparative example. In this comparative example, the metal layer 36b is formed to cover almost the entire of the base metal layer 36a, and the laser spot SP is emitted to the frequency adjustment metal film 36 that does not include the exposed part 361.

As described above, when the laser irradiation is performed to the frequency adjustment metal film 36, the base metal layer 36a is heated so that the metal layer 36b as the upper layer of the base metal layer 36a is melted and evaporated. Then, the base metal layer 36a is exposed to the region where the metal layer 36b has been evaporated. As shown in the comparative example in FIG. 18, Au residue (in the case where the metal layer 36b is made of Au) is sometimes generated on the irradiation line after the predetermined times of laser sweep. The Au residue is a small lump of remaining Au on the edge of the metal layer 36b. The Au residue may come off from the metal layer 36b after completion of the frequency adjustment of the crystal resonator 100 and adhere to the second excitation electrode 112, which may result in undesired shift of the frequency of the crystal resonator 100.

The Au residue shown in the comparative example in FIG. 18 is generated by remaining Au in the shape of a bridge after melting (i.e. generation of a Au bridge) caused by uneven evaporation of the Au on the irradiation line in the middle of the laser sweep. That is, even when the Au bridge itself generated on the irradiation line in the middle of the laser sweep finally disappears, the Au residue is likely to remain at the edge of the Au bridge.

In contrast to the above, in the example shown in FIG. 17, the laser sweep is performed along the exposed part 361 such that at least a part of the laser spot SP includes the exposed part 361. Thus, it is possible to avoid generating the Au bridge on the irradiation line during the laser sweep, which results in prevention of generation of the Au residue. When the generation of the Au residue can be avoided, it is also possible to prevent adhesion of the Au residue that has come off from the metal layer 36b to the second excitation electrode 112.

Also, when the irradiation is performed by linearly scanning the frequency adjustment metal film 36 with the laser as described above, the irradiation to the starting point of the line is unstable, which is derived from a general property of the laser. As an example, when the laser power is strong at the starting point of the line, not only the frequency adjustment becomes difficult, but also the base metal layer 36a may be melted. However, if the entire laser power is reduced according to the power to be at the starting point in order to prevent the melting of the base metal layer 36a, the efficiency of the frequency adjustment is degraded.

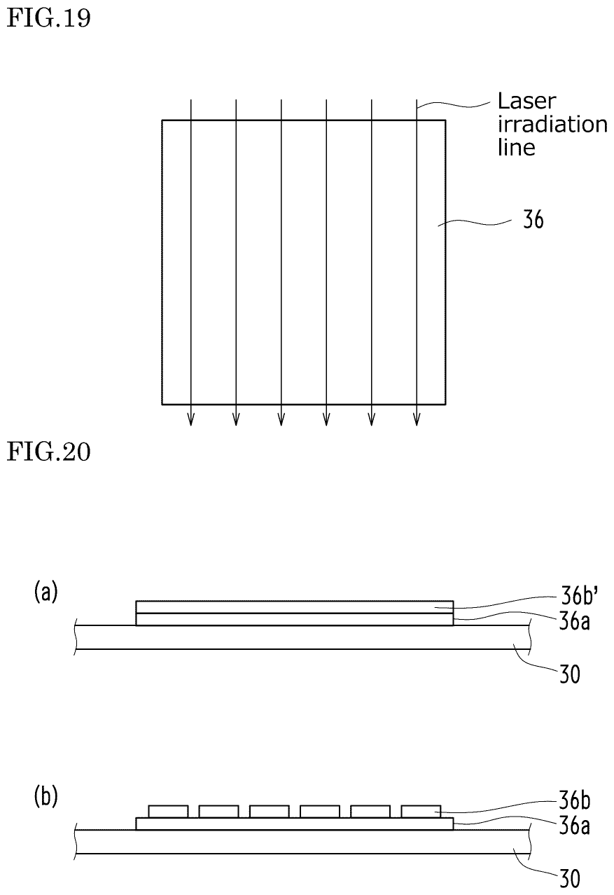

In view of the foregoing, the linear scanning with the laser for the frequency adjustment may be started from the outside of the region of the frequency adjustment metal film 36, as shown in FIG. 19. In this way, the laser power emitted to the frequency adjustment metal film 36 becomes stable, which leads to prevention of melting of the base metal layer 36a without reducing the entire laser power.

The laser emitted to the region outside the frequency adjustment metal film 36 is not blocked by the base metal layer 36a. In this case, if the laser that is not blocked reaches the electrodes and the wirings (especially, the excitation electrode) of the crystal resonator plate 10, it may cause an undesirable result such as damage of the electrodes and the wirings. Therefore, when the laser irradiation is started from the outside of the region of the frequency adjustment metal film 36, the laser is not emitted to the region where the electrodes and the wirings are formed on the crystal resonator plate 10, but is emitted to the region where only the crystal exists. Since the emitted laser passes through the crystal region other than the region where the electrodes and the wirings are formed, it does not cause any problem.

In this case, it is preferable to maintain the relationship “the length of the frequency adjustment metal film 36>the length of the excitation electrode (in this case, the second excitation electrode 112)” in the scanning direction with the laser. The length of the frequency adjustment metal film 36 in this case means the length of at least the base metal layer 36a. As to the metal layer 36b, by making it shorter than the second excitation electrode 112, it is possible to obtain an effect that the evaporated metal can be further reliably adhered to the second excitation electrode 112. Therefore, when the laser irradiation is started from the outside of the region of the frequency adjustment metal film 36, it is most desirable to maintain the relationship “the length of the base metal layer 36a>the length of the second excitation electrode 112>the length of the metal layer 36b” in the scanning direction with the laser.

The frequency adjustment metal film 36 of the crystal resonator 100 having the above-described configuration is formed by the steps indicated in FIGS. 20. First, the base metal layer 36a and a metal layer 36b′ before patterning are formed on the second sealing member 30 (see FIG. 20(a)). Next, a mask is formed on the metal layer 36b′ by photolithography so as to pattern the metal layer 36b′ by etching. Thus, the metal layer 36b after patterning is formed (see FIG. 20(b)).

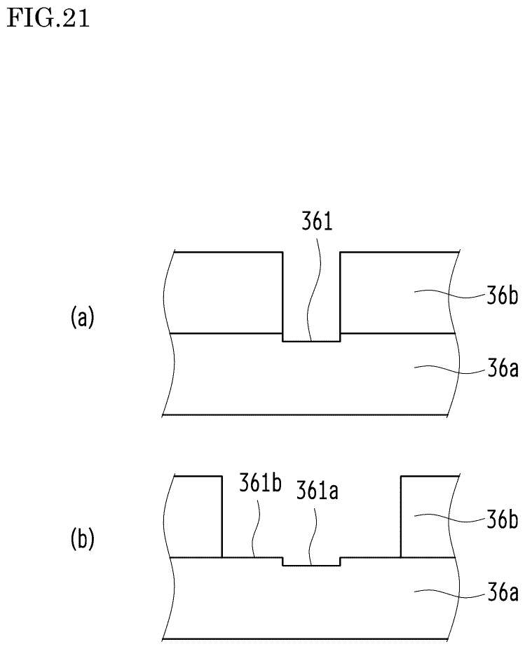

FIG. 21 are enlarged cross-sectional views of the frequency adjustment metal film 36. FIG. 21(a) shows a state before the frequency adjustment, and FIG. 21(b) shows a state after the frequency adjustment. As shown in FIG. 21(a), the frequency adjustment metal film 36 before the frequency adjustment has an exposed part 361 as a part where the metal layer 36b′ has been removed by etching. The base metal layer 36a at the exposed part 361 is affected by the etching and thus has a film thickness smaller than that of the surrounding base metal layer 36a.

On the other hand, in the frequency adjustment metal film 36 after the frequency adjustment as shown in FIG. 21(b), a part of the metal layer 36b is evaporated and removed, which results in the width of the exposed part 361 larger than the width thereof before the frequency adjustment. Here, the exposed part 361 that already exists before the frequency adjustment is referred to as a first exposed part 361a, while the part where the base metal layer 36a is exposed by evaporation of the metal layer 36b at the time of the frequency adjustment is referred to as a second exposed part 361b.

The second exposed part 361b is formed so as to make contact with both the first exposed part 361a and the metal layer 36b in plan view. In the crystal resonator 100 after being subjected to the frequency adjustment, the film thickness of the base metal layer 36a at the first exposed part 361a is smaller than that of the second exposed part 361b. Like this, in the configuration in which the film thickness of the base metal layer 36a is smaller at the first exposed part 361a, the amount of the heat storage in the first exposed part 361a is reduced during the laser irradiation of the frequency adjustment, which contributes to an advantageous effect that the metal layer 36b around the first exposed part 361a is efficiently heated.

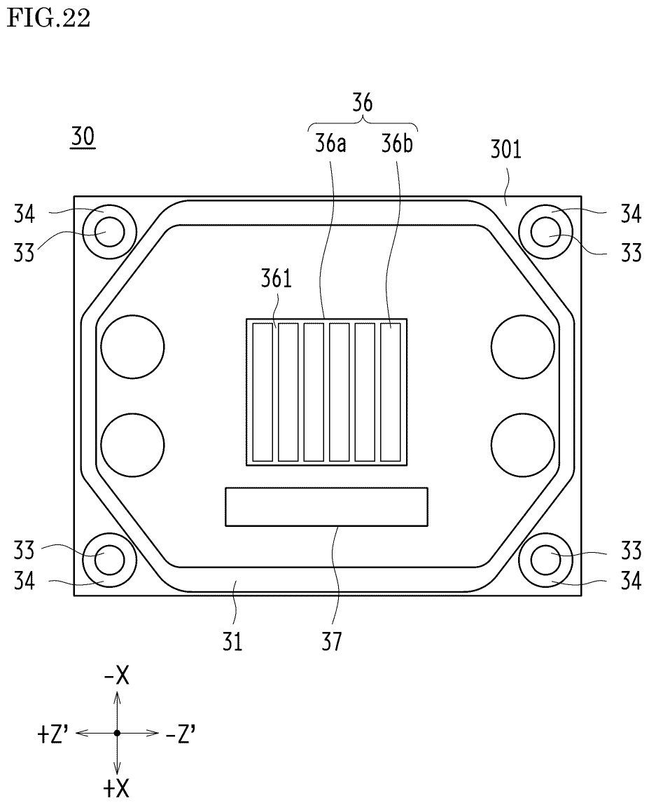

Also in the crystal resonator 100 of this embodiment, the metal layer (for example, a W layer) 37 that is the same as the base metal layer 36a may be formed as a separate layer on a region other than the region where the base metal layer 36a is located (see FIG. 22), so as to cause the metal layer 37 to function as a getter material, similarly to the variation in the first embodiment shown in FIG. 12.

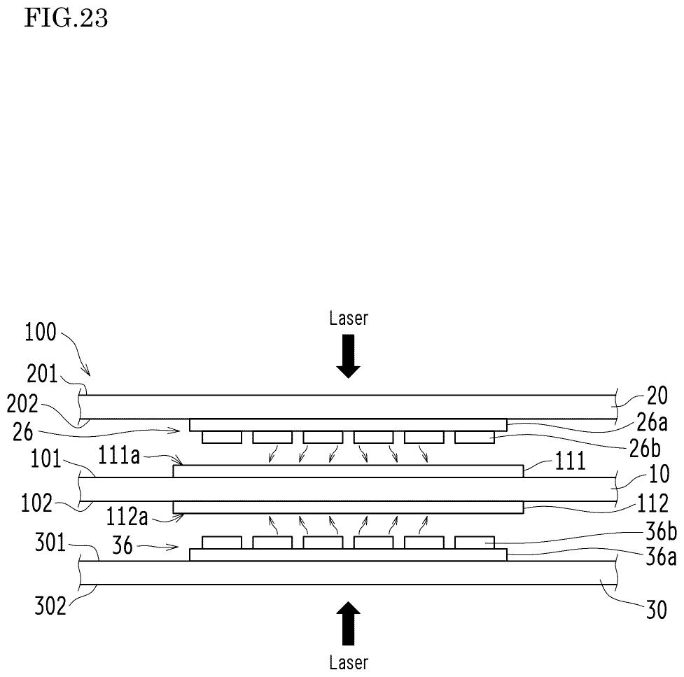

Also, similarly to the variation in the first embodiment, the frequency adjustment metal film is not necessarily required to be formed on the second sealing member 30, and it may be formed on the second main surface 202 of the first sealing member 20, which faces the first excitation electrode 111. Alternatively, as shown in FIG. 23, the frequency adjustment metal film 26 may be formed on the second main surface 202 of the first sealing member 20 while the frequency adjustment metal film 36 is formed on the first main surface 301 of the second sealing member 30. In this case, the frequency adjustment metal film 26 is constituted of the base metal layer 26a and the metal layer 26b laminated on the base metal layer 26a, as in the case of the frequency adjustment metal film 36 of the second sealing member 30.

### Third Embodiment

The essential configuration of the crystal resonator 100 according to this embodiment is similar to the configuration according to the second embodiment. Thus, the description is omitted on the same configuration as that of the second embodiment, and only the characteristic features of this embodiment will be described here.

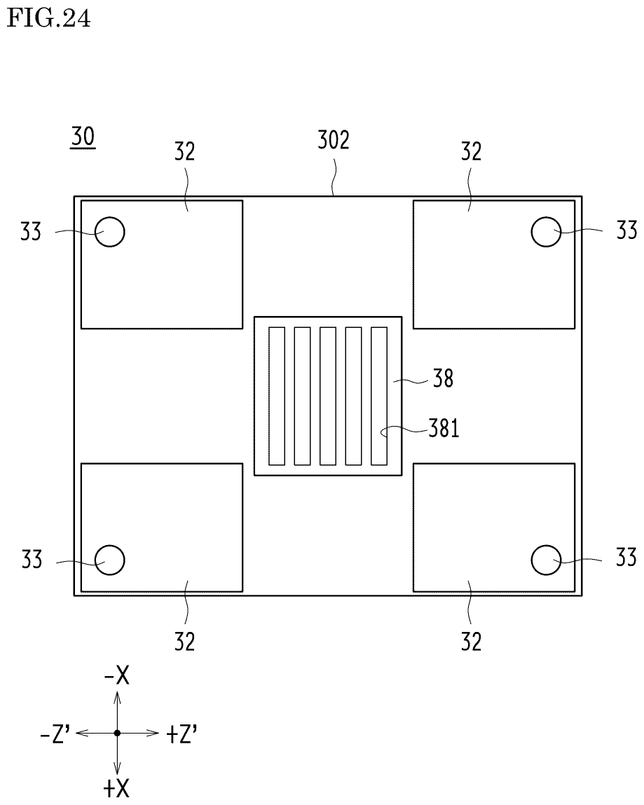

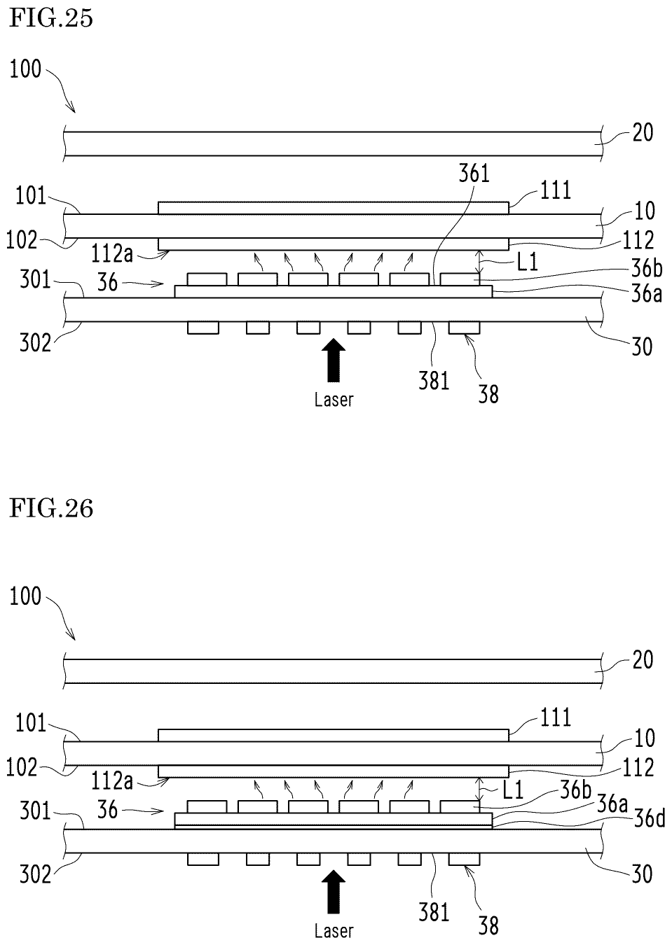

FIG. 24 is a schematic plan view illustrating the second main surface 302 of the second sealing member 30 of the crystal resonator 100 according to this embodiment. FIG. 25 is a schematic cross-sectional view schematically illustrating the method for adjusting the frequency of the crystal resonator 100 according to this embodiment. As shown in FIGS. 14 and 25, the frequency adjustment metal film 36 similar to that in the second embodiment is formed in this embodiment. That is, the metal layer 36b is formed in a stripe pattern on the base metal layer 36a, and the gap between the adjacent stripes of the metal layer 36b is the exposed part 361.

Furthermore, in this embodiment, a shielding film 38 is formed on the second main surface 302 of the second sealing member 30 so as to shield part of the laser emitted when the crystal resonator 100 is subjected to the frequency adjustment, as shown in FIG. 24. In the shielding film 38, a plurality of slits (opening parts) 381 is formed such that the slits 381 have a stripe pattern in the same direction as the direction of the stripes of the metal layer 36b of the frequency adjustment metal film 36. In this embodiment, the favorable conditions (i.e. thickness, material, melting temperature and the like) of the frequency adjustment metal film 36 and the shielding film 38 other than the respective shapes are the same as those in the second embodiment. Also, similarly to the variation of the second embodiment shown in FIG. 16, the auxiliary metal layer 36d may be formed between the base metal layer 36a and the second sealing member 30 (see FIG. 26).

Here, a description is given on the frequency adjustment method of the crystal resonator 100 according to this embodiment. Since the frequency adjustment method of this embodiment is similar to the frequency adjustment method described in the second embodiment, only different points are described while the same points are omitted.

In this embodiment, the frequency adjustment metal film 36 is irradiated by linearly emitting and sweeping the laser spot SP, in the same way as the second embodiment. At this time, the laser sweep is performed from the outside corresponding to the shielding film 38 as shown in FIG. 25, such that at least a part of the laser spot SP includes the exposed part 361.

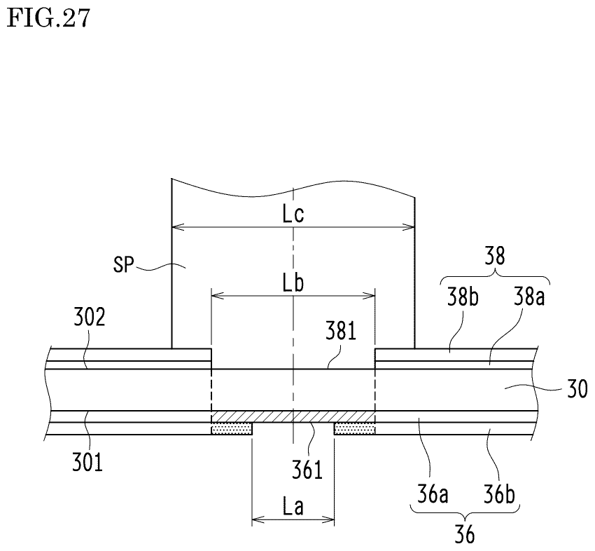

In the crystal resonator 100 of this embodiment as shown in FIG. 27, the frequency adjustment metal film 36 is formed on the first main surface 301 of the second sealing member 30, while the shielding film 38 is formed on the second main surface 302 (i.e. the surface to which the laser is emitted) thereof. It is preferable that the surface of the shielding film 38 is made of a metal (such as Au, Ag, and Al) having a high reflectance to the laser (in this embodiment, a green laser with the wavelength of 532 nm) so that the emitted laser is shielded by the reflection. By making the surface of the shielding film 38 of the metal having a high reflectance, it is possible to prevent the temperature of the shielding film 38 itself from increasing due to the laser irradiation. In this way, the shielding film 38 can have a two-layer structure made of, for example, a Ti layer 38a as a lower layer and a Au layer 38b as an upper layer (surface layer). Also, the shielding film 38 has the slits 381 formed so as to have a stripe pattern in the same direction as the direction of the stripes of the metal layer 36b of the frequency adjustment metal film 36.

The slit 381 is formed larger than the exposed part 361 so as to include the exposed part 361 in plan view. Thus, in this embodiment, the line width Lb of the slit 381 is formed larger than the line width La of the exposed part 361. In this way, the adjacent stripes of the metal layer 36b located on the respective outer sides of the exposed part 361 can be heated via the base metal layer 36a, which leads to an efficient frequency adjustment. Furthermore, the exposed part 361 and the slit 381 are positioned such that their respective centers in the line width direction coincide with each other in plan view. The shielding film 38 and the metal layer 36b are both prepared by forming a mask by photolithography so as to perform patterning by etching. Thus, it is possible to position them with a high accuracy.

As shown in FIG. 27, the frequency adjustment metal film 36 is irradiated with the laser such that the laser spot SP includes the slit 381. More specifically, the line width Lb of the slit 381 is made smaller than the irradiation diameter Lc of the laser spot SP, and the laser spot SP is emitted such that both end parts of the laser spot SP in the line width direction of the slit 381 partially overlap the shielding film 38. In this case, the laser emitted to the overlapped parts of the shielding film 38 is shielded (reflected) by the shielding film 38, and thus does not penetrate the second sealing member 30. Therefore, the laser emitted within the slit 381 penetrates the second sealing member 30 to heat the frequency adjustment metal film 36.

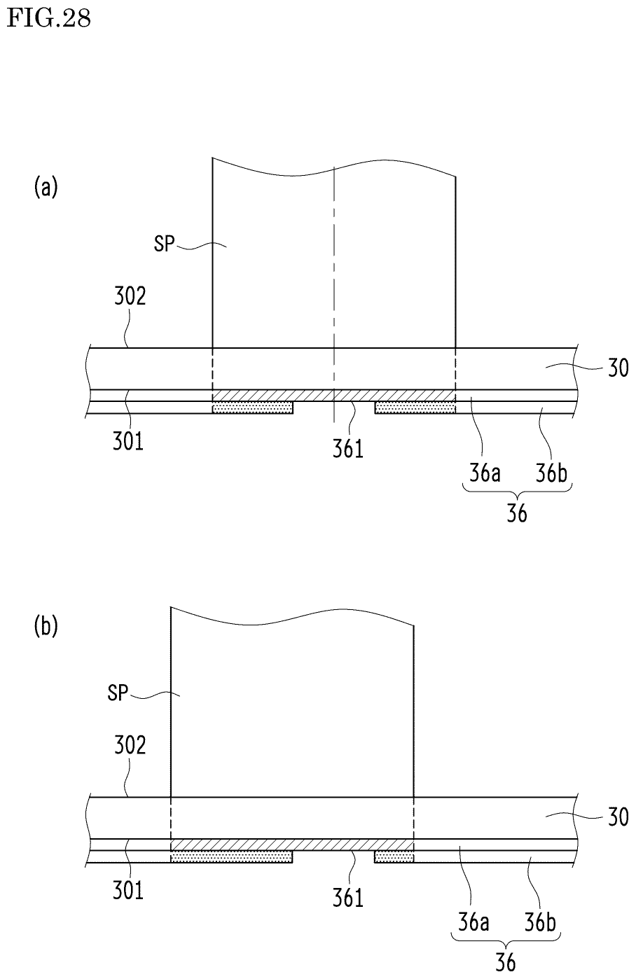

In the crystal resonator 100 as described above, the shielding film 38 is formed on the surface to be irradiated with the laser (in this case, the second main surface 302 of the second sealing member 30). Here, the reason is explained. FIG. 28 are schematic cross-sectional views schematically illustrating the method for irradiating the frequency adjustment metal film 36 with the laser when the frequency adjustment metal film 36 does not have the shielding film 38, as a comparative example. In this comparative example as shown in FIG. 28(a), it is preferable that the center of the laser spot SP is positioned at the center of the exposed part 361 in the line width direction. However, the positioning of the laser spot SP with a high accuracy is not actually performed, and the laser spot SP may be mispositioned with respect to the exposed part 361, as shown in FIG. 28(b).

When the laser spot SP is mispositioned with respect to the exposed part 361, the adjustment amount may be unstable due to the irradiation to the undesirable region. Also, the Au residue (in the case where the metal layer 36b is made of Au) may be generated at the edge of the metal layer 36b on the irradiation line after completion of the laser sweep. The generation of the Au residue in this case is considered to be derived from the mispositioning of the laser spot SP that causes loss of balance between the irradiation area and the amount of heat applied by the laser spot SP with respect to the metal layer 36b. For example, when the laser spot SP is mispositioned as shown in FIG. 28(b), in the metal layer 36b in the left half of the laser spot SP, the amount of heat applied becomes smaller relative to the irradiation area (line area). Accordingly, the Au of this metal layer 36b is melted but not evaporated, and will be finally re-solidified. This re-solidification of the Au generates the Au residue. Such generation of the Au residue may result in an undesired shift of the frequency of the crystal resonator 100 after completion of the frequency adjustment of the crystal resonator 100, as described in the second embodiment.

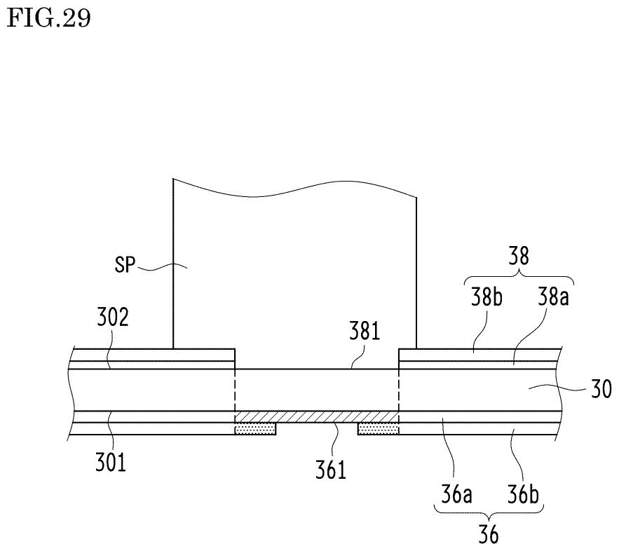

In contrast to the above, in the crystal resonator 100 having the shielding film 38 as shown in FIG. 29, even when the laser spot SP is mispositioned, it is possible to reliably irradiate, with the beam, the region of the metal layer 36b to be heated. Thus, it is possible to perform stable frequency adjustment not depending on the positional accuracy of the laser irradiation device. Furthermore, since the laser irradiation range to the frequency adjustment metal film 36 is regulated by the shielding film 38, it is possible to remarkably reduce the loss of balance between the irradiation area and the amount of heat applied by the laser spot SP with respect to the metal layer 36b. As a result, the generation of the Au residue can also be avoided, which prevents the undesired shift of the frequency of the crystal resonator 100 after completion of the frequency adjustment of the crystal resonator 100.

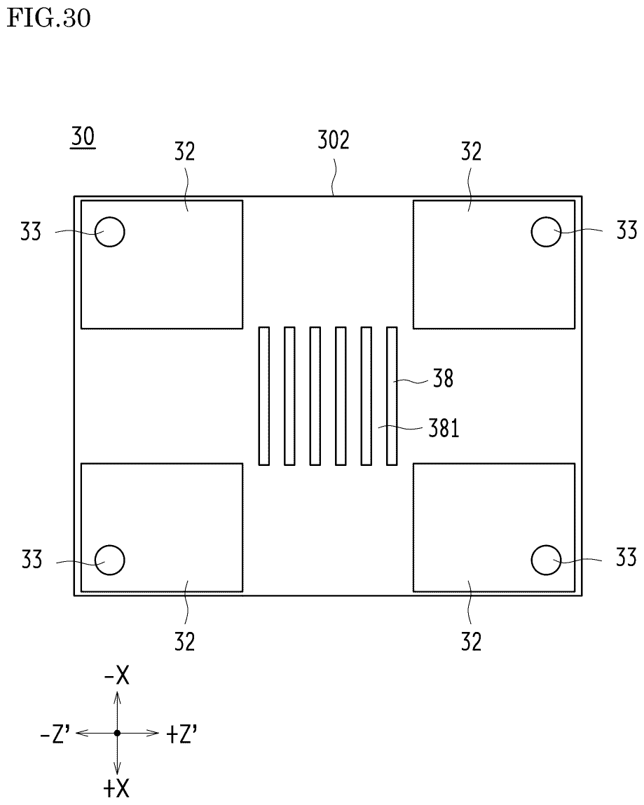

In the example of the shielding film 38 shown in FIG. 24, all four sides of each slit 381 of the shielding film 38 is surrounded by the shielding film 38 so as to be formed as a closed region. In other words, the shielding film 38 shown in FIG. 24 has a frame part that surrounds the entire peripheries of the slits 381. However, for the purpose of avoiding generation of the above-described Au residue, the shape of the shielding film 38 is not necessarily limited thereto. For example, as shown in FIG. 30, a plurality of shielding films 38 may be formed in a stripe pattern, and a slit 381 as an opening part may be provided between the adjacent shielding films 38.

However, the example of the shielding film 38 shown in FIG. 24 still has an advantage specified below. That is, when the irradiation is performed by linearly scanning the frequency adjustment metal film 36 with the laser as described above, the irradiation to the starting point of the line is unstable, which is derived from a general property of the laser. As an example, when the laser power is strong at the starting point of the line, not only the frequency adjustment becomes difficult, but also the base metal layer 36a may be melted. However, if the entire laser power is reduced according to the power to be at the starting point in order to prevent the melting of the base metal layer 36a, the efficiency of the frequency adjustment is degraded.

In contrast to the above, when the shielding film 38 shown in FIG. 24 is adopted and when the linear scanning with the laser for the frequency adjustment is started from a region (i) where is the outside of the region of the slits 381 (i.e. outside of the end part of each slit 381 in the longitudinal direction) and (ii) where the shielding film 38 exists (for example, the frame part on the upper side of the shielding film 38), it is possible to shield, by the shielding film 38, the laser with unstable power at the starting point of the line. In this way, the laser power emitted to the frequency adjustment metal film 36 becomes stable, which leads to prevention of melting of the base metal layer 36a without reducing the entire laser power.

Furthermore, since the shielding film 38 is formed so as to correspond to the frequency adjustment metal film 36 on the second sealing member 30 of the crystal resonator 100, it is possible to obtain an effect that the bent of the second sealing member 30 is reduced. In the crystal resonator 100, the shielding film 38 may be electrically connected to the external electrode terminal 32 that is at the ground (GND) potential when the crystal resonator 100 operates. In this case, the shielding film 38 can serve as a shielding film with respect to the excitation electrode of the crystal resonator 100. In the same way as the above, the frequency adjustment metal film 36 may also be electrically connected to the electrodes or wirings at the ground potential when the crystal resonator 100 operates.

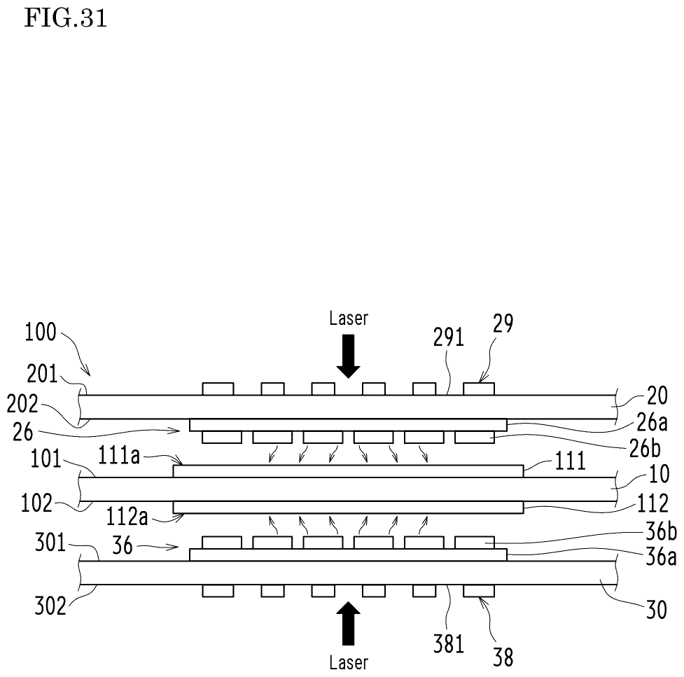

Also, similarly to the variation in the second embodiment, the frequency adjustment metal film is not necessarily required to be formed on the second sealing member 30, and it may be formed on the second main surface 202 of the first sealing member 20, which faces the first excitation electrode 111. Alternatively, as shown in FIG. 31, the frequency adjustment metal film 26 may be formed on the second main surface 202 of the first sealing member 20 while the frequency adjustment metal film 36 is formed on the first main surface 301 of the second sealing member 30. In this case, the frequency adjustment metal film 26 is constituted of the base metal layer 26a and the metal layer 26b laminated on the base metal layer 26a, as in the case of the frequency adjustment metal film 36 of the second sealing member 30. On the first main surface 201 of the first sealing member 20, a shielding film 29 is provided corresponding to the frequency adjustment metal film 26. The shielding film 29 (and slits 291) of the first sealing member 20 has the same configuration as that of the shielding film 38 (and the slits 381) of the second sealing member 30.

### Fourth Embodiment

The essential configuration of the crystal resonator 100 according to this embodiment is similar to the configuration according to the second embodiment. Thus, the description is omitted on the same configuration as that of the second embodiment, and only the characteristic features of this embodiment will be described here.

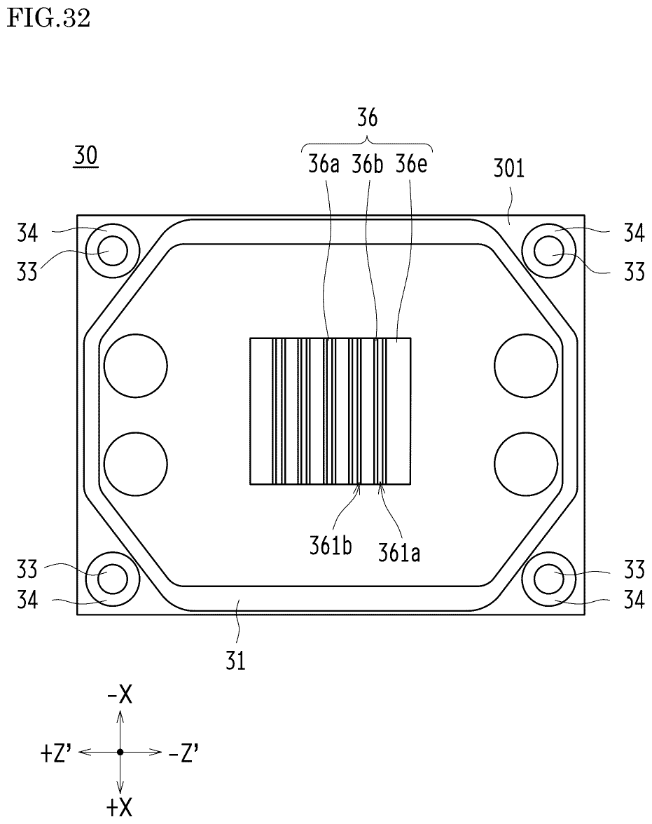

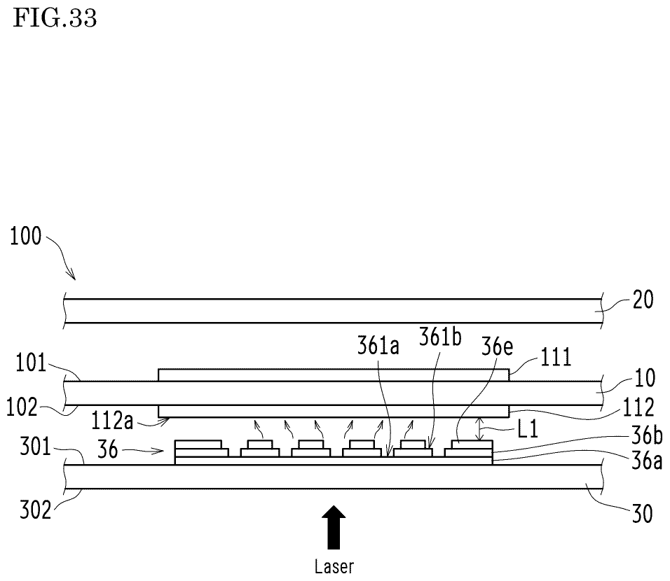

FIG. 32 is a schematic plan view illustrating the first main surface 301 of the second sealing member 30 of the crystal resonator 100 according to this embodiment. FIG. 33 is a schematic cross-sectional view schematically illustrating the method for adjusting the frequency of the crystal resonator 100 according to this embodiment. In this embodiment as shown in FIGS. 32 and 33, the frequency adjustment metal film 36 has a multi-layer structure made of two or more kinds of metals having different melting temperatures (melting points). In the example shown in FIG. 33, a three-layer structure is shown. More specifically, the frequency adjustment metal film 36 is constituted of the base metal layer 36a, the first metal layer 36b laminated on the base metal layer 36a, and a second metal layer 36e laminated on the first metal layer 36b. Here, the first metal layer 36b corresponds to the metal layer 36b in the second and third embodiments.

The melting temperature of the second metal layer 36e is set to be higher than the melting temperature of the first metal layer 36b. The second metal layer 36e may be made of the same material as that of the base metal layer 36a. Thus, the base metal layer 36a and the second metal layer 36e may be made of, for example, W (tungsten). Also, the second metal layer 36e may be made of a material different from that of the base metal layer 36a. For example, the base metal layer 36a may be made of W (tungsten) while the second metal layer 36e may be made of any one of Mo (molybdenum), Ta (tantalum), and Re (rhenium).

The frequency adjustment metal film 36 is provided with an opening part from which a part of the base metal layer 36a is exposed without being covered by the first and the second metal layers 36b and 36e. As shown in FIGS. 33 to 35, the first and the second metal layers 36b and 36e respectively have opening parts 361a and 361b. The opening part 361a of the first metal layer 36b and the opening part 361b of the second metal layer 36e communicate with each other so as to expose the base metal layer 36a therefrom. More specifically, by communicating the opening part 361a of the first metal layer 36b with the opening part 361b of the second metal layer 36e, a base metal-exposed part is formed by a part of the base metal layer 36a exposed without being covered by the first and the second metal layers 36b and 36e. Also, by the opening part 361b of the second metal layer 36e, a first metal-exposed part is formed by a part of the first metal layer 36b exposed without being covered by the second metal layer 36e.

The base metal-exposed part of the base metal layer 36a and the first metal-exposed part of the first metal layer 36b are linearly extended in plan view. Also, the first metal-exposed part of the first metal layer 36b is provided between the base metal-exposed part of the base metal layer 36a and the second metal layer 36e. More specifically, the first metal-exposed parts of the first metal layer 36b are provided on the left and right sides of the base metal-exposed part of the base metal layer 36a so as to interpose the base metal-exposed part therebetween. Also, the respective pieces of the second metal layer 36e are provided on the left and right sides of the base metal-exposed part of the base metal layer 36a, and furthermore of the first metal-exposed parts of the first metal layer 36b provided on the left and right sides of the base metal-exposed part. The base metal-exposed part of the base metal layer 36a as well as the first metal-exposed part of the first metal layer 36b are formed on multiple parts at respectively predetermined intervals. The laser irradiation to the frequency adjustment metal film 36 is performed along the base metal-exposed parts of the base metal layer 36a and the first metal-exposed parts of the first metal layer 36b.

Here, a description is given on the frequency adjustment method of the crystal resonator 100 according to this embodiment. Since the frequency adjustment method of this embodiment is similar to the frequency adjustment method described in the second embodiment, only different points are described while the same points are omitted.

In this embodiment as shown in FIG. 33, the frequency adjustment metal film 36 is irradiated with a laser from the outside of the second sealing member 30 so that the laser penetrates the interior of the second sealing member 30 and heats the base metal layer 36a. Thus, at least part of the first metal layer 36b is melted and evaporated (turned into gas), and the evaporated metal is adhered to the second excitation electrode 112. In this way, the frequency adjustment is performed. More specifically, the first metal layer 36b as the upper layer of the base metal layer 36a is melted by the laser so as to be evaporated from the opening part 361b. Thus, the metal evaporated from the first metal layer 36b is adhered to the second excitation electrode 112. On the other hand, since the second metal layer 36e as the upper layer of the first metal layer 36b has a melting temperature higher than that of the first metal layer 36b, it is hardly melted and remains as a solid.

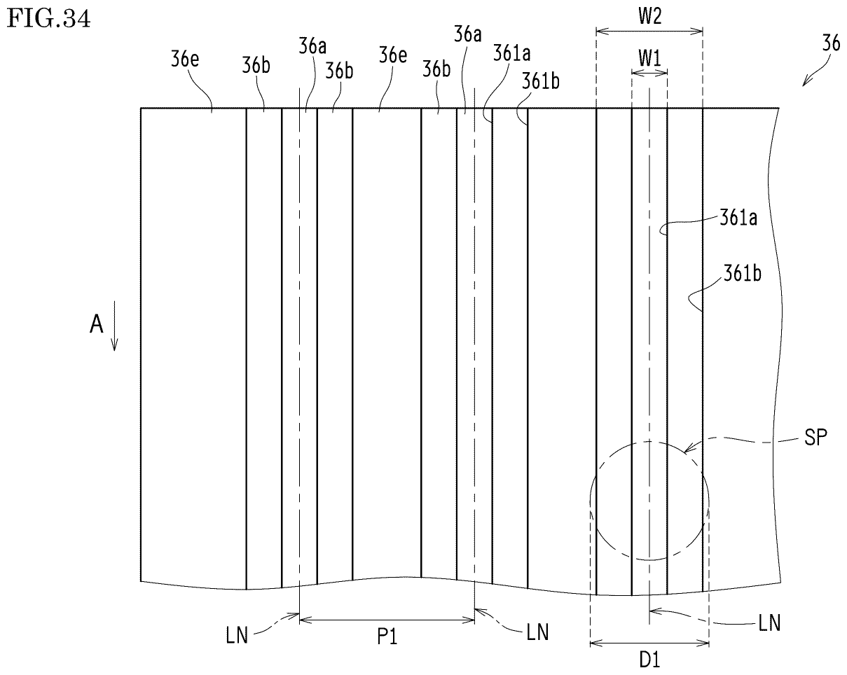

The frequency adjustment metal film 36 is irradiated by linearly emitting and sweeping the laser spot SP. As shown in FIG. 34, the emission of the laser is performed to a desired region of the frequency adjustment metal film 36 by arranging the irradiation lines LN made by sweeping the laser spot SP in parallel with each other. In this case, the sweep direction (direction indicated by the arrow A) of the laser spot SP is the same for all the irradiation lines LN, and the respective irradiation lines LN are set along the base metal-exposed parts of the base metal layer 36a and the first metal-exposed parts of the first metal layer 36b. More specifically, the irradiation line LN is a line along a substantial center (substantial center of the line width W1) of the base metal-exposed part of the base metal layer 36a and furthermore is a line along a substantial center (substantial center of the line width W2) of the first metal-exposed part of the first metal layer 36b.

The sweep of the laser spot SP is performed multiple times repeatedly to each irradiation line LN. After the laser sweep has been performed multiple times to one irradiation line LN, the laser sweep is performed to the next irradiation line LN. The pitch (i.e. the interval in the direction orthogonal to the sweep direction) P1 of the laser sweep is set to be larger than the diameter (irradiation diameter) D1 of the laser spot SP (i.e. P1>D1), and the irradiation lines adjacent to each other in the direction orthogonal to the sweep direction do not interfere with each other (i.e. do not overlap) in plan view. Also, the line width W1 of the base metal-exposed part of the base metal layer 36a as well as the line width W2 of the first metal-exposed part of the first metal layer 36b are set to be smaller than the irradiation diameter D1 of the laser spot SP (i.e. W1<D1 and W2<D1). Thus, respective sides of adjacent lines of the first metal layer 36b are heated by both sides of the laser spot SP that is swept.

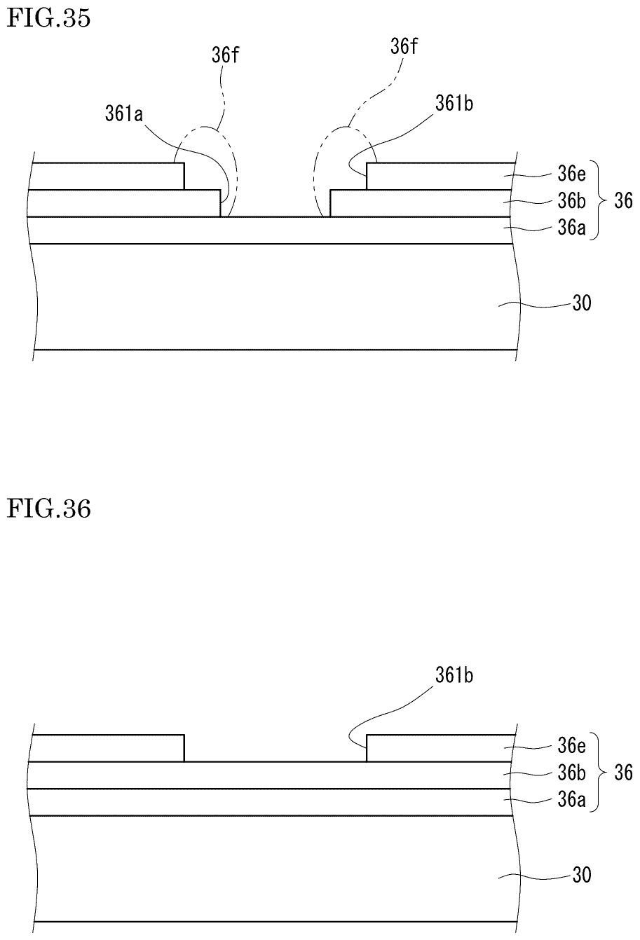

By the laser irradiation to the frequency adjustment metal film 36, the base metal layer 36a is heated and the first metal layer 36b as the upper layer of the base metal layer 36a is melted and evaporated. At this time, part of the melted first metal layer 36b may flow toward the outside of the laser irradiation range. However, in this embodiment as shown in FIG. 35, even when part of the melted first metal layer 36b flows toward the outside of the laser irradiation range, it adheres to the sides of the unmelted first metal layer 36b and the end parts of the second metal layer 36e so as to become a solidified metal 36f. In particular, the first metal layer 36b having the second metal layer 36e thereon is not likely to be melted because the temperature thereof increases gradually compared to the temperature of the first metal layer 36b not having the second metal layer 36e thereon. Furthermore, since the second metal layer 36e serves as a stopper to prevent the flow of the melted first metal layer 36b toward the outside of the laser irradiation range, the melted first metal layer 36b remains within the laser irradiation range (within the laser spot SP). Thus, the heat by the laser irradiation can be efficiently transmitted to the melted first metal layer 36b that remains within the laser irradiation range. In this way, it is possible to prevent decrease of the amount of the frequency adjustment caused by the flow of the part of the melted first metal layer 36b toward the outside of the laser irradiation range.

Furthermore, the metal 36f that adheres to the sides of the first metal layer 36b and the end parts of the second metal layer 36e is solidified in a relatively stable shape. Thus, after completion of the frequency adjustment, it is possible to prevent the metal 36f as the foreign material from scattering outside.

Here, in the frequency adjustment metal film 36 as shown in FIG. 36, only the second metal layer 36e may have the opening part 361b while the first metal layer 36b does not have the opening part. That is, in the frequency adjustment metal film 36, the first metal-exposed part of the first metal layer 36b is formed by the opening part 361b of the second metal layer 36e, but the base metal-exposed part of the base metal layer 36a is not formed. In this case, by the laser irradiation to the frequency adjustment metal film 36, the base metal layer 36a is heated and the first metal layer 36b at the first metal-exposed part is melted and evaporated. Then, by adhering the melted first metal layer 36b that is flowing toward the outside of the laser irradiation range to the unmelted first metal layer 36b and the second metal layer 36e, it is possible to prevent the flow of the melted first metal layer 36b toward the outside of the laser irradiation range, and also to maintain the melted first metal layer 36b within the laser irradiation range (within the laser spot SP). Furthermore, no processing step is needed to form the opening part in the first metal layer 36b, which simplifies the production process of the frequency adjustment metal film 36. In addition, it is possible to ensure a large area of the first metal layer 36b to be used for the frequency adjustment.

When the second metal layer 36e is made of a metal different from that of the base metal layer 36a, it is possible to improve a heat absorption effect by the second metal layer 36e by making the second metal layer 36e of a material having a high specific heat or a high thermal conductivity. For example, it is possible to enhance the heat absorption effect by the second metal layer 36e by making, for example, the second metal layer 36e of Mo (molybdenum), and the base metal layer 36a of W (tungsten).

On the other hand, when the second metal layer 36e is made of the same metal as that of the base metal layer 36a, it is possible to simplify the production process of the frequency adjustment metal film 36 and thus to improve productivity. For example, by making both the second metal layer 36e and the base metal layer 36a of W (tungsten), it is not any more needed to consider the melting of the second metal layer 36e, which leads to a stable frequency adjustment.

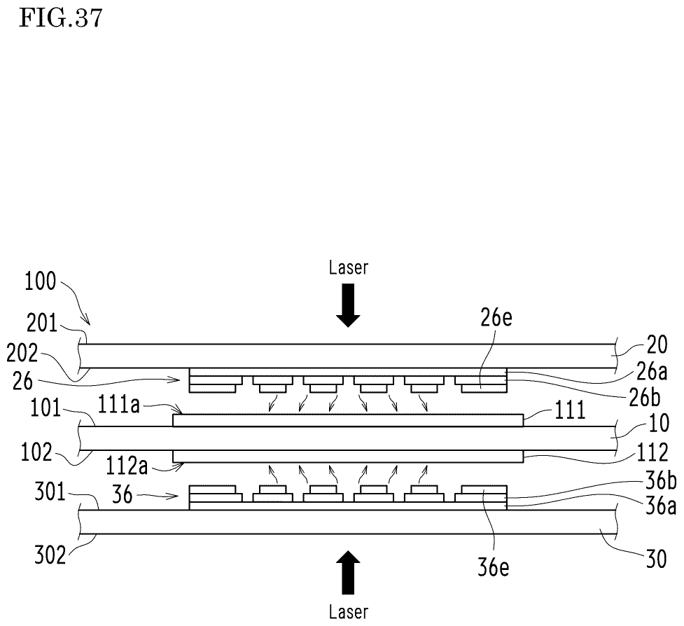

Also, similarly to the variation in the second embodiment, the frequency adjustment metal film is not necessarily required to be formed on the second sealing member 30, and it may be formed on the second main surface 202 of the first sealing member 20, which faces the first excitation electrode 111. Alternatively, as shown in FIG. 37, the frequency adjustment metal film 26 may be formed on the second main surface 202 of the first sealing member 20 while the frequency adjustment metal film 36 is formed on the first main surface 301 of the second sealing member 30. In this case, the frequency adjustment metal film 26 of the first sealing member 20 is constituted of the base metal layer 26a, the first metal layer 26b, and a second metal layer 26e laminated in this order, as in the case of the frequency adjustment metal film 36 of the second sealing member 30 of this embodiment.

### Fifth Embodiment

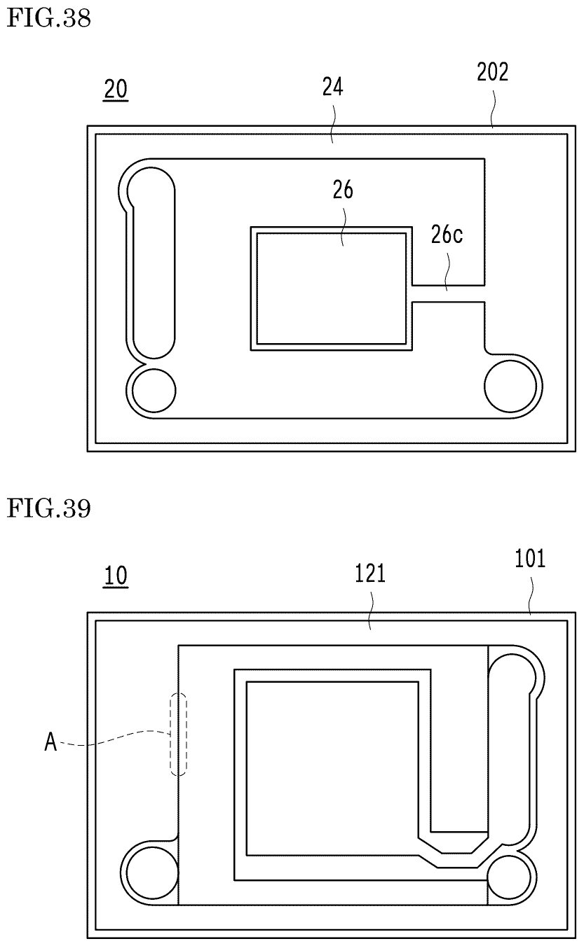

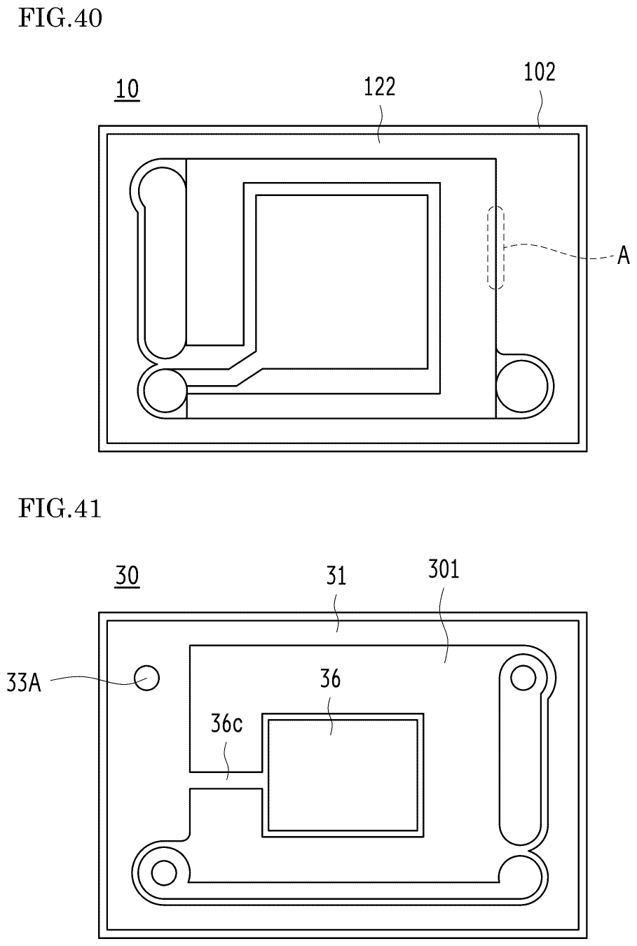

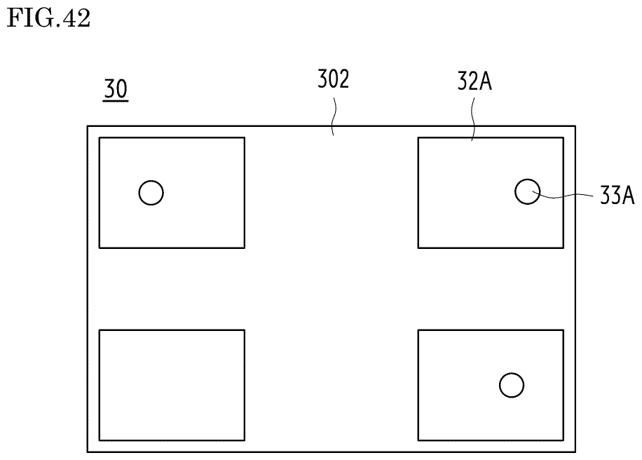

The frequency adjustment metal films 26 and 36 described in the first to the fourth embodiments may be electrically connected to the electrodes or wirings at the ground (GND) potential when the crystal resonator 100 operates. A configuration of the crystal resonator 100 in which the frequency adjustment metal films 26 and 36 can be connected to the GND is exemplarily described with reference to FIGS. 38 to 42. FIG. 38 is a schematic plan view illustrating the second main surface 202 of the first sealing member 20 of the crystal resonator 100. FIG. 39 is a schematic plan view illustrating the first main surface 101 of the crystal resonator plate 10 of the crystal resonator 100. FIG. 40 is a schematic plan view illustrating the second main surface 102 of the crystal resonator plate 10 of the crystal resonator 100. FIG. 41 is a schematic plan view illustrating the first main surface 301 of the second sealing member 30 of the crystal resonator 100. FIG. 42 is a schematic plan view illustrating the second main surface 302 of the second sealing member 30 of the crystal resonator 100.

In the crystal resonator 100 as described in the first to the fourth embodiments, an IC chip is assumed to be mounted, along with the crystal resonator 100, on the first sealing member 20 so as to construct a crystal oscillator. Based on this premise, wirings and electrodes are designed. In contrast to the above, in the crystal resonator 100 shown in FIGS. 38 to 42, no IC chip is assumed to be mounted on the first sealing member 20. Therefore, wirings and electrodes are designed in a manner different from that in the first to the fourth embodiments. However, in the description below, the same reference numerals as those in the crystal resonator 100 described in the first to the fourth embodiments are used to refer to the components that have the same functions.

In the crystal resonator 100 according to this embodiment, an external electrode terminal 32A on the second main surface 302 of the second sealing member 30, which is located in the upper right of FIG. 42, is an electrode to be connected to the GND. This external electrode terminal 32A is connected to the sealing-member-side second bonding pattern 31 formed on the first main surface 301 of the second sealing member 30 via a through hole 33A (see FIGS. 41 and 42). Also, the sealing-member-side second bonding pattern 31 is integrated with the resonator-plate-side second bonding pattern 122 formed on the second main surface 102 of the crystal resonator plate 10 by bonding the second sealing member 30 to the crystal resonator plate 10.

In the crystal resonator plate 10, the resonator-plate-side second bonding pattern 122 formed on the second main surface 102 is electrically connected to the resonator-plate-side first bonding pattern 121 formed on the first main surface 101. The resonator-plate-side second bonding pattern 122 can be electrically connected to the resonator-plate-side first bonding pattern 121 by, for example, forming a metal film on the inner wall surface of the crystal resonator plate 10 (for example, the inner wall surface in a region A in FIGS. 39 and 40). Also, the resonator-plate-side first bonding pattern 121 is integrated with the sealing-member-side first bonding pattern 24 formed on the second main surface 202 of the first sealing member 20 by bonding the crystal resonator plate 10 to the first sealing member 20.

In the crystal resonator 100 of this embodiment as described above, the electrical path is formed by the external electrode terminal 32A, the through hole 33A, the sealing-member-side second bonding pattern 31, the resonator-plate-side second bonding pattern 122, the resonator-plate-side first bonding pattern 121 and the sealing-member-side first bonding pattern 24 in this order. Thus, this electrical path can be at the ground potential.

When the frequency adjustment metal film 26 is formed on the second main surface 202 of the first sealing member 20, the frequency adjustment metal film 26 is connected to the sealing-member-side first bonding pattern 24 by a connection wiring 26c, as shown in FIG. 38. In this case, the connection wiring 26c can be formed, for example, simultaneously with the base metal layer 26a of the frequency adjustment metal film 26. Also, when the frequency adjustment metal film 36 is formed on the first main surface 301 of the second sealing member 30, the frequency adjustment metal film 36 is connected to the sealing-member-side second bonding pattern 31 by a connection wiring 36c, as shown in FIG. 41. In this case, the connection wiring 36c can be formed, for example, simultaneously with the base metal layer 36a of the frequency adjustment metal film 36.

In this way, by connecting the frequency adjustment metal films 26 and 36 to the GND, the frequency adjustment metal films 26 and 36 can be used as shielding films against ESD (high frequency noise).

### Sixth Embodiment

In the first to the fifth embodiments as described above, the crystal resonator 100 having the three-layer structure is used, in which the crystal resonator plate 10 is interposed between the first sealing member 20 and the second sealing member 30. However, the crystal resonator having the structure other than the above may also be used. For example, a crystal resonator may be used, which has a structure in which the crystal resonator plate is housed inside a base that has a recess part and that is made of an insulating material such as ceramic, glass, and crystal. To this base, a lid is bonded.

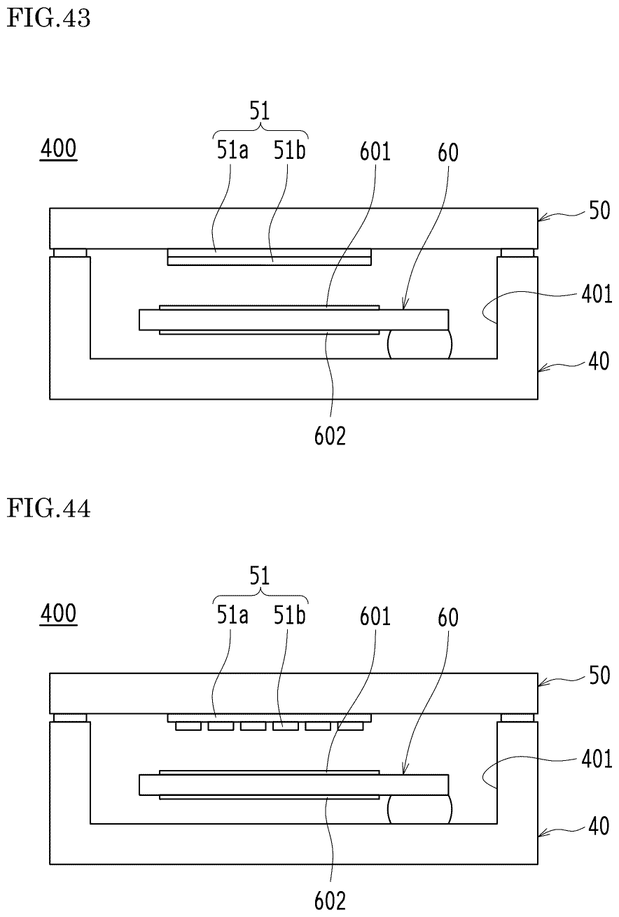

FIG. 43 is a schematic configuration diagram schematically illustrating the configuration of a crystal resonator (piezoelectric resonator device) 400 according to this embodiment. In the crystal resonator 400 as shown in FIG. 43, a crystal resonator plate (vibrating part) 60 is housed inside a base 40 having a recess part 401, and a lid 50 is bonded to the base 40. A first excitation electrode 601 and a second excitation electrode 602 are formed respectively on both main surfaces of the crystal resonator plate 60.

In the crystal resonator 400, a frequency adjustment metal film 51 is formed on a rear surface (i.e. a surface facing the base 40) of the lid 50 as a sealing member. The frequency adjustment metal film 51 is constituted of a base metal layer 51a and a metal layer 51b in the same way as the frequency adjustment metal film 36 of the first embodiment. Also, the lid 50 is made of a material having a high transmittance with respect to the laser (for example, crystal or glass). Thus, after the crystal resonator plate 60 has been hermetically sealed in the package by bonding the lid 50 to the base 40, the base metal layer 51a can be heated by the laser irradiation to the surface of the lid 50 (i.e. the lid not facing the base 40).

In the crystal resonator 400 also, the frequency adjustment metal film 51 is irradiated with the laser from the outside of the base 40 so that the laser penetrates the interior of the base 40 and heats the base metal layer 51a. Thus, at least part of the metal layer 51b is melted and evaporated (turned into gas), and the evaporated metal is adhered to the excitation electrode (in this example, the first excitation electrode 601). In this way, the frequency adjustment is performed.

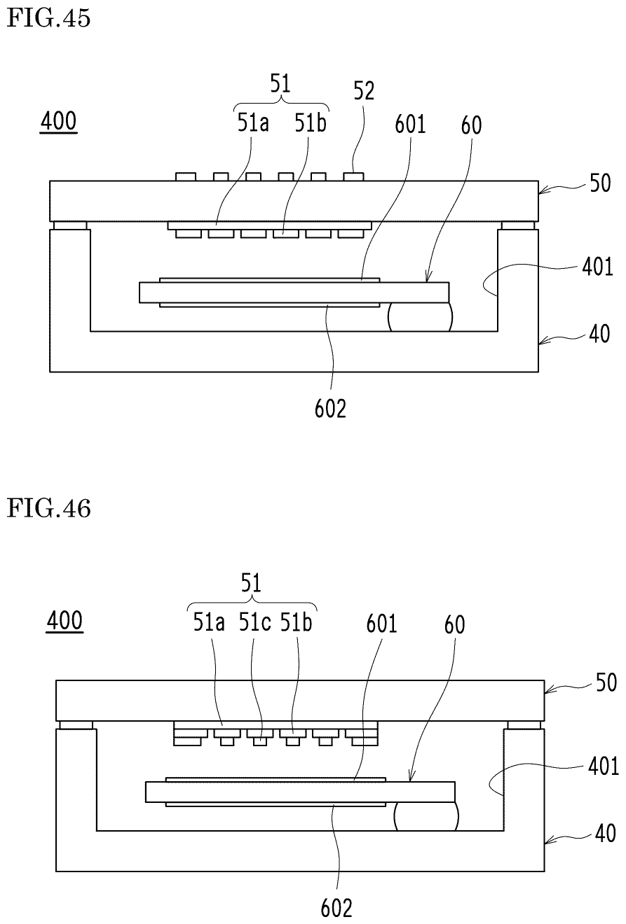

In the crystal resonator 400 shown in FIG. 43, the frequency adjustment metal film 51 has the same structure as that of the frequency adjustment metal film 36 of the first embodiment. However, as shown in FIGS. 44 and 46, the frequency adjustment metal film 51 may have the same structure as the frequency adjustment metal film 36 of the second embodiment or the fourth embodiment. Also, as shown in FIG. 45, a shielding film 52 may be formed on the surface of the lid 50, similarly to the third embodiment.

The foregoing embodiments are to be considered in all respects as illustrative and not limiting. The technical scope of the invention is indicated by the appended claims rather than by the foregoing description, and all modifications and changes that come within the meaning and range of equivalency of the claims are intended to be embraced therein.

This application claims priority based on Patent Application No. 2022-008170 filed in Japan on Jan. 21, 2022, Patent Application No. 2022-009290 filed in Japan on Jan. 25, 2022, and Patent Application No. 2022-013237 filed in Japan on Jan. 31, 2022. The entire contents thereof are hereby incorporated in this application by reference.

### DESCRIPTION OF THE REFERENCE NUMERALS

10 Crystal resonator plate
11 Vibrating part
20 First sealing member (sealing member)
30 Second sealing member (sealing member)
36, 51 Frequency adjustment metal film
36a, 51a Base metal layer
36b, 51b Metal layer
361 Exposed part
361a First exposed part
361b Second exposed part
38, 29, 52 Shielding film
381, 291 Slit (opening part)
100, 400 Crystal resonator (piezoelectric resonator device)
111, 601 First excitation electrode
112, 602 Second excitation electrode
301 First main surface
40 Base
50 Lid (sealing member)
60 Crystal resonator plate (vibrating part)

1. A piezoelectric resonator device in which a vibrating part having an excitation electrode is hermetically sealed by a sealing member, wherein
a frequency adjustment metal film made of a base metal layer and a metal layer laminated thereon is formed on a main surface of the sealing member on a side facing the excitation electrode,
the base metal layer has a melting temperature higher than a melting temperature of the metal layer, and
a difference between the melting temperature of the base metal layer and the melting temperature of the metal layer is not less than 1500 K.

2. A piezoelectric resonator device in which a vibrating part having an excitation electrode is hermetically sealed by a sealing member, wherein
a frequency adjustment metal film made of a base metal layer and a metal layer laminated thereon is formed on a main surface of the sealing member on a side facing the excitation electrode,
a material of the metal layer is selected from the group consisting of Au (gold), Ag (silver), and Al (aluminum), and
a material of the base metal layer is selected from the group consisting of W (tungsten), Mo (molybdenum), Ta (tantalum), and Re (rhenium).

3. The piezoelectric resonator device according to claim 1, wherein
the frequency adjustment metal film is provided with an exposed part as a part of the base metal layer that is not covered by the metal layer but is exposed,
the exposed part is constituted of: a first exposed part; and a second exposed part at which a film thickness of the base metal layer is larger than a film thickness of the base metal layer at the first exposed part, and
the second exposed part is formed so as to make contact with both the first exposed part and the metal layer in plan view.

4. The piezoelectric resonator device according to claim 3, wherein
the first exposed part and the second exposed part are linearly formed.

5. The piezoelectric resonator device according to claim 1, wherein
the frequency adjustment metal film is provided with an exposed part as a part of the base metal layer that is not covered by the metal layer but is exposed,
a shielding film is formed on a main surface of the sealing member, which is opposite to the main surface of the sealing member on the side facing the excitation electrode, so as to correspond to the frequency adjustment metal film, and
the shielding film is provided with an opening part that is formed to include the exposed part in plan view.

6. A method for adjusting a frequency of a piezoelectric resonator device in which a vibrating part having an excitation electrode is hermetically sealed by a sealing member, wherein
the piezoelectric resonator device is the piezoelectric resonator device according to claim 1, and
the method includes the steps of:
irradiating the frequency adjustment metal film with a beam from an outside of the sealing member so that the beam penetrates an interior of the sealing member and heats the base metal layer; and melting and evaporating at least part of the metal layer so that an evaporated part of the metal layer is adhered to the excitation electrode.

7. The method for adjusting a frequency of a piezoelectric resonator device according to claim 6, wherein
the frequency adjustment metal film is provided with an exposed part as a part of the base metal layer that is not covered by the metal layer but is exposed, and
the method includes the steps of:
irradiating the frequency adjustment metal film including at least the exposed part in plan view with the beam from the outside of the sealing member so that the beam penetrates the interior of the sealing member and heats the base metal layer; and melting and evaporating at least part of the metal layer so that an evaporated part of the metal layer is adhered to the excitation electrode.

8. The method for adjusting a frequency of a piezoelectric resonator device according to claim 7, wherein
the exposed part is formed on a plurality of locations at predetermined intervals.

9. The method for adjusting a frequency of a piezoelectric resonator device according to claim 7, wherein
the exposed part is linearly formed, and
the beam is emitted along the line of the exposed part.

10. The method for adjusting a frequency of a piezoelectric resonator device according to claim 9, wherein
a line width of the exposed part is smaller than an irradiation diameter of the beam.

11. The method for adjusting a frequency of a piezoelectric resonator device according to claim 9, wherein
the beam is emitted such that a beam spot includes the exposed part and two lines of the metal layer respectively adjacent to the exposed part.

12. The method for adjusting a frequency of a piezoelectric resonator device according to claim 6, wherein
the frequency adjustment metal film is provided with an exposed part as a part of the base metal layer that is not covered by the metal layer but is exposed,
a shielding film is formed on a main surface of the sealing member, which is opposite to the main surface of the sealing member on the side facing the excitation electrode, so as to correspond to the frequency adjustment metal film,
the shielding film is provided with an opening part that is formed to include the exposed part in plan view, and
the method includes the steps of:
irradiating the frequency adjustment metal film including at least the opening part in plan view with the beam from the outside of the sealing member via the shielding film so that the beam penetrates the interior of the sealing member within a region of the opening part and heats the base metal layer; and melting and evaporating at least part of the metal layer so that an evaporated part of the metal layer is adhered to the excitation electrode.

13. The method for adjusting a frequency of a piezoelectric resonator device according to claim 12, wherein
an opening width of the opening part of the shielding film is smaller than an irradiation diameter of the beam.

14. The method for adjusting a frequency of a piezoelectric resonator device according to claim 12, wherein
the exposed part is linearly formed while the opening part is linearly formed so as to correspond to the exposed part, and
the beam is emitted along the line of the exposed part.

15. The method for adjusting a frequency of a piezoelectric resonator device according to claim 12, wherein
the exposed part and the opening part are formed respectively on a plurality of locations at predetermined intervals.

16. The method for adjusting a frequency of a piezoelectric resonator device according to claim 12, wherein
the shielding film is provided with a frame part on a periphery of the opening part, and
a position from where an irradiation with the beam is started is within a region of the frame part in plan view.

17. The piezoelectric resonator device according to claim 2, wherein
the frequency adjustment metal film is provided with an exposed part as a part of the base metal layer that is not covered by the metal layer but is exposed,
the exposed part is constituted of: a first exposed part; and a second exposed part at which a film thickness of the base metal layer is larger than a film thickness of the base metal layer at the first exposed part, and
the second exposed part is formed so as to make contact with both the first exposed part and the metal layer in plan view.

18. The piezoelectric resonator device according to claim 17, wherein
the first exposed part and the second exposed part are linearly formed.

19. The piezoelectric resonator device according to claim 2, wherein
the frequency adjustment metal film is provided with an exposed part as a part of the base metal layer that is not covered by the metal layer but is exposed,
a shielding film is formed on a main surface of the sealing member, which is opposite to the main surface of the sealing member on the side facing the excitation electrode, so as to correspond to the frequency adjustment metal film, and
the shielding film is provided with an opening part that is formed to include the exposed part in plan view.

20. A method for adjusting a frequency of a piezoelectric resonator device in which a vibrating part having an excitation electrode is hermetically sealed by a sealing member, wherein
the piezoelectric resonator device is the piezoelectric resonator device according to claim 2, and
the method includes the steps of:
irradiating the frequency adjustment metal film with a beam from an outside of the sealing member so that the beam penetrates an interior of the sealing member and heats the base metal layer, and melting and evaporating at least part of the metal layer so that an evaporated part of the metal layer is adhered to the excitation electrode.
